(19) United States
(12) Patent Application Publication
(10) Pub. No.: US 2009/0137103 A1
(43) Pub. Date: May 28, 2009

(54) METHOD FOR MANUFACTURING SEMICONDUCTOR DEVICE

(75) Inventor: Shunpei Yamazaki, Tokyo (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 12/276,530

(22) Filed: Nov. 24, 2008

(30) Foreign Application Priority Data
Nov. 27, 2007 (JP) 2007-305294

(51) Int. Cl. H01L 21/20

(52) U.S. Cl. 438/479; 257/E21.09

(57) ABSTRACT

In order to improve the quality of a microcrystalline semiconductor film which is formed at an early stage of deposition, a microcrystalline semiconductor film near an interface with a base insulating film is formed under a deposition condition in which a deposition rate is low but the quality of a film to be formed is high; then, a microcrystalline semiconductor film is further deposited at a deposition rate which is increased stepwise or gradually. The microcrystalline semiconductor film is formed in a reaction chamber which is provided in a deposition chamber with space around the reaction chamber, by a chemical vapor deposition method. Further, a scaling gas is supplied into the space to help place the reaction chamber in an ultrahigh vacuum, whereby the concentration of an impurity in the microcrystalline semiconductor film near the interface with the base insulating film is reduced.

### BACKGROUND OF THE INVENTION

1. Field of the Invention

The present invention relates to a semiconductor device having a circuit including a thin film transistor (hereinafter also referred to as a TFT) and a method for manufacturing the semiconductor device. For example, the present invention relates to an electrooptic device typified by a liquid crystal display panel, and to an electronic device which has a light-emitting display device including an organic light-emitting element as a part thereof.

In this specification, a “semiconductor device” generally refers to a device which can function by utilizing semiconductor characteristics; an electrooptic device, a display device such as a light-emitting display device, a semiconductor circuit, and an electronic device are all included in semiconductor devices.

2. Description of the Related Art

In recent years, technology for forming thin film transistors (TFTs) using a thin semiconductor film (with a thickness of from several tens of nanometers to several hundreds of nanometers, approximately) formed over a substrate having an insulating surface has been attracting attention. Thin film transistors are applied to a wide range of electronic devices such as ICs or electrooptic devices, and prompt development of thin film transistors that are to be used as switching elements in display devices, in particular, is being pushed.

As a switching element in a display device, a thin film transistor including an amorphous semiconductor film, a thin film transistor including a polycrystalline semiconductor film, or the like is used.

In a case of a thin film transistor including an amorphous semiconductor film, an amorphous semiconductor film such as a hydrogenated amorphous silicon film is used; therefore, there is limitation on the process temperature, and heating at a temperature of greater than or equal to 400° C. at which hydrogen is released from the film, intense laser beam irradiation which roughens a surface due to evaporation of hydrogen from the film, and the like are not performed. The hydrogenated amorphous silicon film is an amorphous silicon film having electric characteristics improved by bonding hydrogen to dangling bonds, thereby making the dangling bonds disappear.

Further, as a method for forming a polycrystalline semiconductor film such as a polysilicon film, a technique that includes the following steps is known: dehydrogenation treatment for reducing a hydrogen concentration is performed in advance to an amorphous silicon film in order to prevent the surface thereof from getting rough; a pulsed excimer laser beam is processed into a linear shape with an optical system; and the dehydrogenated amorphous silicon film is scanned with the linear laser beam, thereby being crystallized.

A thin film transistor in which a polycrystalline semiconductor film is used for a channel formation region has advantages that mobility is higher than that of a thin film transistor in which an amorphous semiconductor film is used for a channel formation region by two or more orders of magnitude, and a pixel portion and a peripheral driver circuit of a display device can be formed over the same substrate. However, the thin film transistor in which a polycrystalline semiconductor film is used for a channel formation region requires a more complicated process than the thin film transistor in which an amorphous semiconductor film is used for a channel formation region because of crystallization of the semiconductor film. Thus, there are problems such as a reduction in yield and an increase in cost.

Reference 1 (U.S. Pat. No. 5,591,987) has disclosed an FET (field effect transistor) in which a channel formation region is formed of a semiconductor having a mixture of a crystalline structure and a noncrystalline structure.

Further, as a switching element in a display device, a thin film transistor including a microcrystalline semiconductor film is used (see Reference 2: Japanese Published Patent Application No. H4-242724; and Reference 3: Japanese Published Patent Application No. 2005-49832).

As a conventional method for manufacturing a thin film transistor, a technique is known in which after forming an amorphous silicon film over a gate insulating film, a metal film is formed thereover, and the metal film is irradiated with diode laser, whereby the amorphous silicon film is changed into a microcrystalline silicon film (see Reference 4: Toshiaki Arai et al., “SID 07 DIGEST” 2007, pp. 1370-1373). According to this method, the metal film formed over the amorphous silicon film is formed to convert optical energy of the diode laser into thermal energy, and needs to be removed later in order to complete a thin film transistor. That is to say, in the above method, the amorphous silicon film is heated only with heat conduction from the metal film to form the microcrystalline silicon film.

### SUMMARY OF THE INVENTION

A microcrystalline semiconductor film can be formed by a plasma CVD method as well as a method in which amorphous silicon is irradiated with a laser beam to form a microcrystalline semiconductor film. In this plasma CVD method, a silane gas is diluted with hydrogen, whereby a microcrystalline semiconductor film can be formed. In an inverted-staggered TFT structure, in which a semiconductor layer is provided over a gate electrode with a gate insulating film interposed therebetween, a semiconductor region which is formed at an early stage of deposition serves as a channel formation region. Therefore, the higher the quality of the semiconductor region which is formed at the early stage of deposition is, the higher the electric characteristics (e.g., field effect mobility) of a TFT can be.

However, in the method in which a microcrystalline semiconductor film is formed by a plasma CVD method, by dilution with hydrogen, that is, by increase in the flow rate of a hydrogen gas, a deposition rate decreases.

A low deposition rate results in a long deposition time. Thus, more impurities can be included in the film during deposition, and the impurities can cause deterioration in electric characteristics of a TFT.

If a hydrogen concentration is reduced in order to increase a deposition rate of a microcrystalline semiconductor film, a region to be a channel formation region can be an amorphous semiconductor region and electric characteristics of a thin film transistor can deteriorate.

Further, an inverted-staggered TFT in which a microcrystalline semiconductor film is used for a channel formation region can have higher field effect mobility than an inverted-staggered TFT in which an amorphous semiconductor film is used for a channel formation region, but tends to have higher off current.

The present invention provides a method for forming a microcrystalline semiconductor film having excellent quality, and a method for manufacturing a semiconductor device having higher field effect mobility and lower off current than a TFT in which an amorphous silicon film is used for a channel formation region.

In order to improve the quality of a semiconductor region which is formed at an early stage of deposition, a gate insulating film is formed over a gate electrode; a microcrystalline semiconductor film near an interface with the gate insulating film is formed under a first deposition condition in which a deposition rate is low but the quality of a film to be formed is high; and then, a microcrystalline semiconductor film is further formed under a second deposition condition with a higher deposition rate. The deposition rate may be increased either stepwise or gradually. That is to say, the microcrystalline semiconductor film is formed in a growth direction of the microcrystalline semiconductor film from the substrate side while the deposition rate is increased stepwise or gradually. Either microcrystalline semiconductor film is formed by a plasma CVD method in a reaction chamber which is provided in (inside) a deposition chamber into which a sealing gas can be supplied, with space around the reaction chamber. The sealing gas is hydrogen and/or a rare gas. If a rare gas is used, it is preferable to use argon. “Gradual deposition condition” means that the change in deposition condition is smooth with respect to time, and “stepwise deposition condition” means that the deposition condition increases or decreases in a stepwise manner with respect to time. For example, when a gas flow rate is changed as a deposition condition and a graph is made where the horizontal axis represents time and the vertical axis represents gas flow rates, the gradual deposition condition ascends or descends in a smooth curve or a straight line, and the stepwise deposition condition ascends or descends in a stepwise line.

According to one aspect of the present invention disclosed in this specification, a method for manufacturing a semiconductor device includes the steps of forming a gate electrode over a substrate having an insulating surface, forming an insulating film over the gate electrode, forming a microcrystalline semiconductor film over the insulating film, and forming a buffer layer over and in contact with the microcrystalline semiconductor film. In forming the microcrystalline semiconductor film, a deposition condition is changed stepwise or gradually so that a deposition rate of a first region near an interface with the buffer layer is higher than that of a second region near an interface with the insulating film. The buffer layer is not necessarily formed; if the buffer layer is not formed, a semiconductor film including an n-type impurity element is formed, and a periphery of an interface of the microcrystalline semiconductor film with the semiconductor film including the n-type impurity element is defined as the first region.

The first deposition condition in which a deposition rate is low but the quality of a film to be formed is high is set as follows: the ultimate pressure is lowered to be an ultrahigh vacuum (UHV) ranging from approximately 1×10⁻⁸ Pa to 1×10⁻⁵ Pa (1×10⁻¹⁰ Torr to 1×10⁻⁷ Torr, approximately) so that a residual gas such as oxygen, nitrogen, or H₂O in a vacuum chamber (reaction chamber) can be reduced as much as possible in advance before deposition; a source gas (reaction gas) with high purity is supplied into the reaction chamber; and the substrate temperature in deposition is set to be higher than or equal to 100° C. and lower than 300° C.

Further, in attaining a degree of ultrahigh vacuum in the reaction chamber, in order to prevent a gas such as oxygen, nitrogen, or H₂O from entering the reaction chamber through a gap such as a gap in a sealed portion of an outer wall of the reaction chamber, a deposition chamber is provided for an outside of the reaction chamber and is designed to be supplied with a sealing gas including hydrogen and/or a rare gas. A portion through which the gas passes, such as a gap in a wall in the reaction chamber, is minute; it is effective to supply the sealing gas into the deposition chamber in making the gas that leaks from the deposition chamber to the reaction chamber a viscous flow. When the reaction chamber is closed and a degree of ultrahigh vacuum is made, it is preferable to supply the sealing gas consecutively to the deposition chamber, which is provided for the outside of the reaction chamber

Further, any gas may be used as the sealing gas as long as it hardly has an influence on formation of the microcrystalline semiconductor film and has high pumping speed in a vacuum pump. An example of the sealing gas is hydrogen or a rare gas typified by argon.

The deposition chamber when the sealing gas is supplied may contain either an atmosphere in which the pressure therein is higher than an atmospheric pressure or a reduced-pressure atmosphere. Note that if the atmosphere in the deposition chamber and the reaction chamber becomes continuous in taking a substrate into the reaction chamber, it is preferable to make the pressure in the deposition chamber lower than an atmospheric pressure and to make the capacity of the deposition chamber as small as possible because it is necessary to evacuate the deposition chamber to a high vacuum.

According to another aspect of the present invention disclosed in this specification, a method for manufacturing a semiconductor device includes the steps of forming a gate electrode over a substrate having an insulating surface, forming an insulating film over the gate electrode, taking the substrate into a reaction chamber, forming a microcrystalline semiconductor film by supplying a source gas (reaction gas) into the reaction chamber under a first deposition condition in which the substrate temperature is set to be higher than or equal to 100° C. and lower than 300° C., forming a microcrystalline semiconductor film further in the same reaction chamber under a second deposition condition in which at least one of the substrate temperature, the amount of electric power, the flow rate of the source gas (reaction gas), and the degree of vacuum is different from that under the first deposition condition, and forming a buffer layer over the microcrystalline semiconductor film. Also in this case, the buffer layer is not necessarily formed; if the buffer layer is not formed, a semiconductor film including an n-type impurity element is formed, and a periphery of an interface of the microcrystalline semiconductor film with the semiconductor film including the n-type impurity element is defined as a first region.

In the microcrystalline semiconductor film which is obtained under the first deposition condition, an oxygen concentration is lower than or equal to 1×10¹⁷/cm³. In forming a microcrystalline semiconductor film, oxygen or nitrogen inhibits crystallization and may possibly act as a donor if it is taken in by a semiconductor film; therefore, oxygen or nitrogen is an impurity that should especially be reduced. The quality of the microcrystalline semiconductor film which is obtained under the first deposition condition contributes to increase in on current and improvement in field effect mobility of a TFT which is completed later.

Further, it is preferable that before forming the microcrystalline semiconductor film, the reaction chamber be baked (at from 200° C. to 300° C.) in advance to remove a residual gas mainly containing moisture which exists in the reaction chamber so that the inside of the reaction chamber can have a pressure environment with a degree of ultrahigh vacuum. Furthermore, an inner wall of the reaction chamber may also be heated (at from 50° C. to 300° C.) during formation of the microcrystalline semiconductor film to promote a film formation reaction.

Further, it is acceptable as long as a deposition rate under the second deposition condition is higher than that of the first deposition condition. For example, a flow ratio of a silane gas to a hydrogen gas is changed and the concentration of hydrogen may be reduced within a range that allows formation of the microcrystalline semiconductor film. Further, the deposition rate under the second deposition condition may be increased by having a substrate temperature that is higher that that under the first deposition condition, for example, a substrate temperature of higher than or equal to 300° C. Furthermore, the deposition rate under the second deposition condition may be increased by having larger power than that under the first deposition condition. Still furthermore, the deposition rate may be increased by adjusting an evacuation valve such as a conductance valve of the reaction chamber so that the degree of vacuum under the second deposition condition can be different from that under the first deposition condition.

Still furthermore, under the second deposition condition with a higher deposition rate than that under the first deposition condition, high-frequency power may be applied for a certain period of time to decompose a silane gas with plasma; application of high-frequency power may be stopped for a certain period of time to stop generation of plasma; and such a sequence may be repeated. Under the first deposition condition, continuous discharge is performed in a first deposition period; under the second deposition condition, a deposition rate is made to be higher than that under the first deposition condition by a method in which a plurality of discharge-stop-periods are provided in a second deposition period by turning off high-frequency power. Note that deposition time of the microcrystalline semiconductor film includes the first deposition period in which deposition is performed under the first deposition condition, and the second deposition period in which deposition is performed under the second deposition condition. A method for forming a film in which discharge time and discharge-stop time are selected as appropriate is also called an “intermittent discharge plasma CVD method.” In this case, a microcrystalline semiconductor film is formed under the first deposition condition by a continuous discharge plasma CVD method in which a source gas (reaction gas) is affected continuously by discharge of high-frequency power, and a microcrystalline semiconductor film is further formed in the same reaction chamber under the second deposition condition by an intermittent discharge (also referred to as pulsed) plasma CVD method in which a source gas (reaction gas) is affected intermittently by discharge of high-frequency power. Here, the continuous discharge means discharge which is caused by high-frequency power with a temporally continuous wave.

Still furthermore, under the second deposition condition with a higher deposition rate than the first deposition condition, the inner wall of the reaction chamber in which the microcrystalline semiconductor film is formed may be heated at a higher temperature than the substrate temperature, to form the microcrystalline semiconductor film. If the substrate temperature under the first deposition condition is 100° C., by the inner wall of the reaction chamber being at 150° C., the microcrystalline semiconductor film can be formed efficiently over a substrate surface with a lower temperature than that of the inner wall of the reaction chamber.

In addition, it is preferable that after making the degree of vacuum in the reaction chamber greater than or equal to 1×10⁻⁸ Pa and less than 1×10⁻⁵ Pa, a hydrogen gas or a rare gas be supplied into the reaction chamber and plasma be generated to remove a residual gas mainly containing moisture in the reaction chamber, so that the concentrations of oxygen and nitrogen in the reaction chamber is reduced before taking in a substrate.

Further, after making the degree of vacuum in the reaction chamber greater than or equal to 1×10⁻⁸ Pa and less than 1×10⁻⁵ Pa, a silane gas may be supplied into the reaction chamber to change oxygen in an exhaust apparatus connected to the reaction chamber into silicon oxide, so that oxygen in the reaction chamber may further be reduced before taking in the substrate. Furthermore, in order to prevent a metal element such as aluminum from entering during formation of the microcrystalline semiconductor film, before taking in the substrate, a silane gas may be supplied into the reaction chamber to generate plasma for performing treatment to form a film on the inner wall (also called “precoating treatment”).

Since the deposition rate is low under the first deposition condition, when a film thickness is made to be thick in particular, deposition time becomes long; consequently, an impurity such as oxygen or nitrogen tends to enter the film. Accordingly, by sufficiently reducing oxygen, nitrogen, and moisture in the reaction chamber in this manner before taking in the substrate, an impurity such as oxygen or nitrogen scarcely enters the film even when the deposition time is long, and this is important in terms of improving the quality of the microcrystalline semiconductor film that is formed later.

Further, after taking the substrate in the reaction chamber, plasma treatment with a rare gas such as argon or hydrogen plasma treatment may be performed in order to remove water adsorbed on the substrate before formation of the microcrystalline semiconductor film, so that an oxygen or nitrogen concentration in the microcrystalline semiconductor film may be reduced. It is preferable that the oxygen concentration be lower than or equal to 1×10¹⁷/cm³.

As described above, it is also important to reduce oxygen, nitrogen, and moisture of the substrate sufficiently after taking the substrate in the reaction chamber in order to improve the quality of the microcrystalline semiconductor film that is formed later.

Even when the first deposition condition at an early stage of deposition is changed to the second deposition condition with a higher deposition rate at a later stage of the deposition, microcrystals have been formed in advance, which can be used as nuclei to deposit a microcrystalline semiconductor film with high quality. Further, by forming microcrystals in advance, a deposition rate at the later stage of the deposition can be increased.

Compared to the amount of time it takes to obtain a desired film thickness by film formation under the first deposition condition alone, the desired film thickness can be obtained in a shorter amount of time by performing film formation under the second deposition condition after film formation under the first deposition condition, in the same reaction chamber. Further, if the thickness of the microcrystalline semiconductor film is made to be small by film formation under the first deposition condition alone, there is a possibility that an effect of a buffer layer that is stacked later becomes significant and the field effect mobility of a thin film transistor is reduced,

In addition, since the microcrystalline semiconductor film obtained under the first deposition condition tends to react with oxygen, by changing the first deposition condition to the second deposition condition with a higher deposition rate, the film near an interface with a gate insulating film can be protected. The quality of the microcrystalline semiconductor film which is obtained under the second deposition condition contributes to reduction in off current of a TFT that is formed later.

The microcrystalline semiconductor film which is obtained by changing the deposition condition in two steps includes at least column-like crystals and the oxygen concentration in the film is lower than or equal to 1×10¹⁷/cm³. The total thickness of the microcrystalline semiconductor film which is obtained by changing the deposition condition in two steps is in the range of from 5 nm to 100 nm, preferably, 10 nm to 30 nm.

As long as an early deposition condition is a condition under which a high quality microcrystalline semiconductor film is formed, the microcrystalline semiconductor film is not limited to being formed under a deposition condition changed in two steps, and may be formed under a deposition condition that is changed in three or more steps. Further, the deposition condition can be changed gradually.

The above microcrystalline semiconductor film is more apt to react with oxygen than an amorphous semiconductor film; thus, it is preferably protected without being exposed to the atmosphere, by stacking a buffer layer that does not include crystal grains thereover. The buffer layer is formed in a reaction chamber which is different from that used for forming the microcrystalline semiconductor film, with a substrate temperature that is higher than that under the first and second deposition conditions, for example, from 300° C. to 400° C. Typically, the buffer layer is formed with a thickness of from 30 nm to 400 nm inclusive, preferably from 40 nm to 300 nm inclusive. In addition, the buffer layer is formed using an amorphous silicon film having a higher defect density than that of the microcrystalline semiconductor film. With the use of the amorphous silicon film having a higher defect density for the buffer layer, off current of a TFT that is completed later can be reduced.

The microcrystalline semiconductor film tends to have n-type conductivity by mixture of impurities; therefore, it is preferable that the deposition condition be adjusted so that the microcrystalline semiconductor film can assume an i-type, by adding a slight amount of trimethyl boron gas or the like to the source gas. By adding a slight amount of trimethyl boron gas or the like to the source gas that mainly includes a silane gas and a hydrogen gas, threshold voltage of the thin film transistor can be controlled.

In this specification, a microcrystalline semiconductor film is a film including a semiconductor having an intermediate structure between amorphous and crystalline (including single-crystalline and polycrystalline) structures. This semiconductor is in a third state, in which the semiconductor is stable in free energy, and is a crystalline semiconductor having short-range order and lattice distortion; and column-like or needle-like crystals thereof with a diameter of from 0.5 nm to 20 nm grow in a direction of the normal to a surface of a substrate. Further, the microcrystalline semiconductor film includes both a microcrystalline semiconductor and an amorphous semiconductor. A Raman spectrum of microcrystalline silicon, which is a typical example of a microcrystalline semiconductor, is located in lower wave numbers than 520 cm⁻¹, which represents a peak of a Raman spectrum of single-crystalline silicon. That is to say, a peak of a Raman spectrum of microcrystalline silicon lies between 520 cm⁻¹ and 480 cm⁻¹, which represent a peak of a Raman spectrum of single-crystalline silicon and a peak of a Raman spectrum of amorphous silicon, respectively.

The buffer layer may also be formed in the same reaction chamber as that for forming the microcrystalline semiconductor film although throughput is lowered when a plurality of substrates are treated. If the buffer layer is formed in the same reaction chamber for forming the microcrystalline semiconductor film, an interface between the layers can be formed without being contaminated with contaminating impurity elements when the substrate is transferred; thus, variation in characteristics of the thin film transistor can be reduced.

After the above manufacturing process, the semiconductor film including the n-type impurity element is formed over the buffer layer; the source and drain electrodes are formed over the semiconductor film including the n-type impurity element; the semiconductor film including the n-type impurity element is etched to form source and drain regions; and a part of the buffer layer is etched away so that regions overlapping with the source and drain regions can remain, to form a thin film transistor.

In addition, a recessed portion is formed in the buffer layer in order to reduce leakage current between the source electrode and the drain electrode.

Further, the semiconductor film including an n-type impurity element (an n⁺ layer) is provided between the buffer layer and the source and drain electrodes. The buffer layer is provided between the n⁺ layer and the microcrystalline semiconductor film so as to prevent a contact therebetween. Therefore, the n⁺ layer, the buffer layer, and the microcrystalline semiconductor film are stacked below the source electrode. In a similar manner, the n⁺ layer, the buffer layer, and the microcrystalline semiconductor film are stacked below the drain electrode. With such a stacked-layer structure and a large thickness of the buffer layer, withstand voltage can be improved. Further, with a large thickness of the buffer layer, a recessed portion can be formed in a part of the buffer layer without exposing the microcrystalline semiconductor film, which tends to be oxidized.

When the thin film transistor obtained as described above is turned on, a region near the interface with the gate insulating film in the microcrystalline semiconductor film with high quality which is formed under the first deposition condition serves as a channel formation region. When the thin film transistor is turned off, the recessed portion obtained by etching the part of the buffer layer serves as a path where a slight amount of off current flows. Accordingly, compared to a conventional thin film transistor including a single amorphous silicon layer or a conventional thin film transistor including a single microcrystalline silicon layer, a ratio of on current to off current can be increased and switching characteristics are excellent, which leads to improvement in contrast of a display panel.

In accordance with a manufacturing method of the present invention, field effect mobility of the thin film transistor obtained can be higher than 1 and lower than or equal to 50, preferably from 3 to 10 inclusive. Therefore, the thin film transistor in which the microcrystalline semiconductor film obtained according to the manufacturing method of the present invention is used for a channel formation region has current-voltage characteristics represented by a curve with a steep slope in a rising portion, has an excellent response as a switching element, and can operate at high speed.

A light-emitting device including the thin film transistor which is obtained according to the manufacturing method of the present invention can suppress variation in threshold voltage of the thin film transistor, which leads to improvement in reliability.

In addition, a liquid crystal display device including the thin film transistor which is obtained according to the manufacturing method of the present invention can increase field effect mobility, and thus can increase a driving frequency of a driver circuit. Since the driver circuit can operate at high speed, quadruplication of a frame frequency, black frame insertion, or the like can be realized.

### BRIEF DESCRIPTION OF DRAWINGS

In the accompanying drawings:

FIGS. 1A to 1D are cross-sectional views illustrating a manufacturing method of the present invention;

FIGS. 2A to 2D are cross-sectional views illustrating a manufacturing method of the present invention;

FIGS. 3A to 3C are cross-sectional views illustrating a manufacturing method of the present invention;

FIG. 4 is a top view illustrating a method for manufacturing method of the present invention;

FIG. 5 is a diagram showing an example of a timing chart illustrating a process for forming a microcrystalline semiconductor film;

FIGS. 6A and 6B are a cross-sectional view showing a plasma CVD apparatus and a schematic diagram of a gas flow when a sealing gas is supplied, respectively;

FIGS. 7A and 7B are a perspective view and a top view, respectively, showing a plasma CVD apparatus;

FIGS. 8A to 8D are diagrams illustrating multi-tone photomasks applicable to the present invention;

FIGS. 9A and 9B are cross-sectional views showing a manufacturing process of the present invention;

FIGS. 10A to 10C are cross-sectional views showing a manufacturing process of the present invention;

FIGS. 11A and 11B are cross-sectional views showing a manufacturing process of the present invention;

FIGS. 12A to 12C are top views showing a manufacturing process of the present invention;

FIG. 13 is a diagram illustrating an example of a liquid crystal display device;

FIG. 14 is a diagram illustrating an example of a liquid crystal display device;

FIG. 15 is a diagram illustrating an example of a liquid crystal display device;

FIG. 16 is a diagram illustrating an example of a liquid crystal display device;

FIG. 17 is a diagram illustrating an example of a liquid crystal display device;

FIG. 18 is a diagram illustrating an example of a liquid crystal display device;

FIG. 19 is a diagram illustrating an example of a liquid crystal display device;

FIG. 20 is a diagram illustrating an example of a liquid crystal display device;

FIG. 21 is a diagram illustrating an example of a liquid crystal display device;

FIG. 22 is a diagram illustrating an example of a liquid crystal display device;

FIG. 23 is a diagram illustrating an example of a liquid crystal display device;

FIG. 24 is a diagram illustrating an example of a liquid crystal display device;

FIG. 25 is a diagram illustrating an example of a liquid crystal display device;

FIG. 26 is a diagram illustrating an example of a liquid crystal display device;

FIGS. 27A and 27B are cross-sectional views illustrating an example of a method for manufacturing a light-emitting device;

FIGS. 28A to 28C are cross-sectional views illustrating pixels applicable to light-emitting devices;

FIGS. 29A to 29C are perspective views illustrating display panels;

FIGS. 30A to 30D are perspective views illustrating electronic appliances including light-emitting devices or liquid crystal display devices;

FIG. 31 is a diagram illustrating an electronic appliance including a light-emitting device;

FIG. 32 is a block diagram illustrating a structure of a display device;

FIGS. 33A and 33B are a top view and a cross-sectional view, respectively, illustrating a display panel; and

FIGS. 34A and 34B are a top view and a cross-sectional view, respectively, illustrating a display panel.

### DETAILED DESCRIPTION OF THE INVENTION

### Embodiment Modes

Hereinafter, embodiment modes of the present invention are described. It is easily understood by those skilled in the art that the present invention can be carried out in many different modes, and the modes and details disclosed herein can be modified in various ways without departing from the spirit and scope of the present invention. Therefore, the present invention should not be interpreted as being limited to the description of the embodiment modes to be given below.

### Embodiment Mode 1

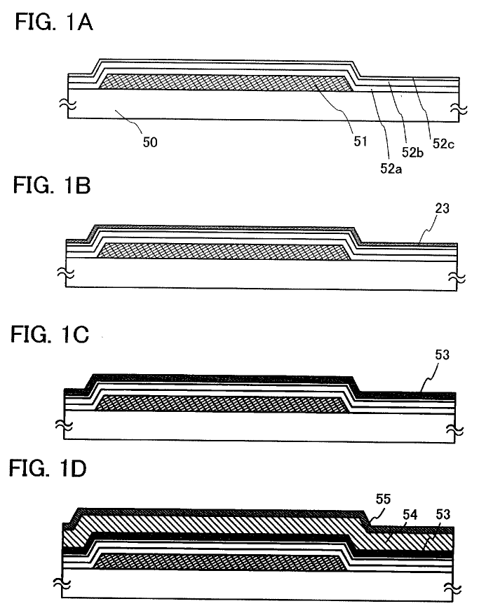

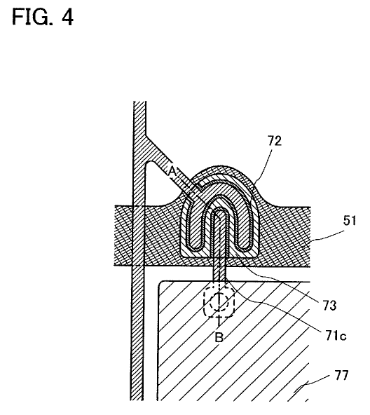

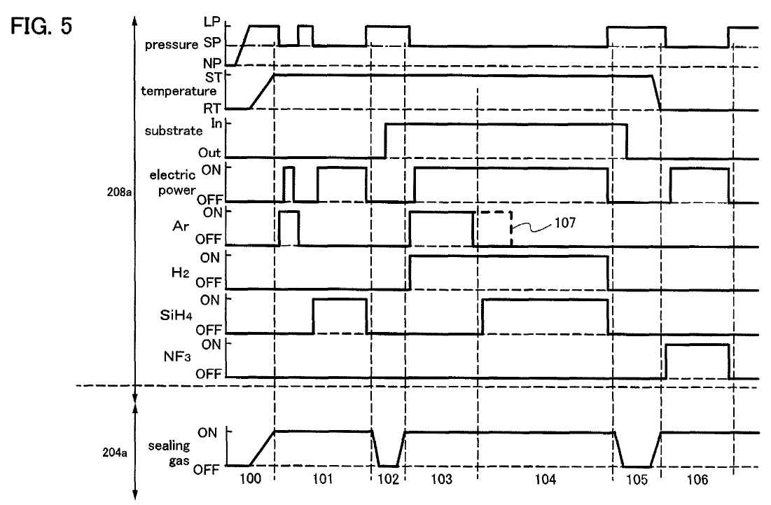

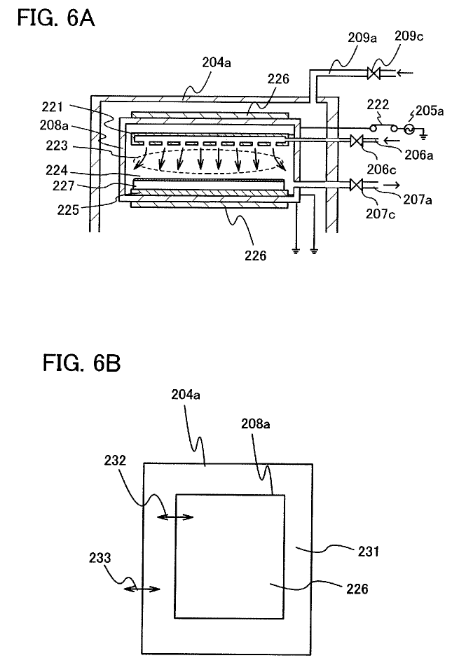

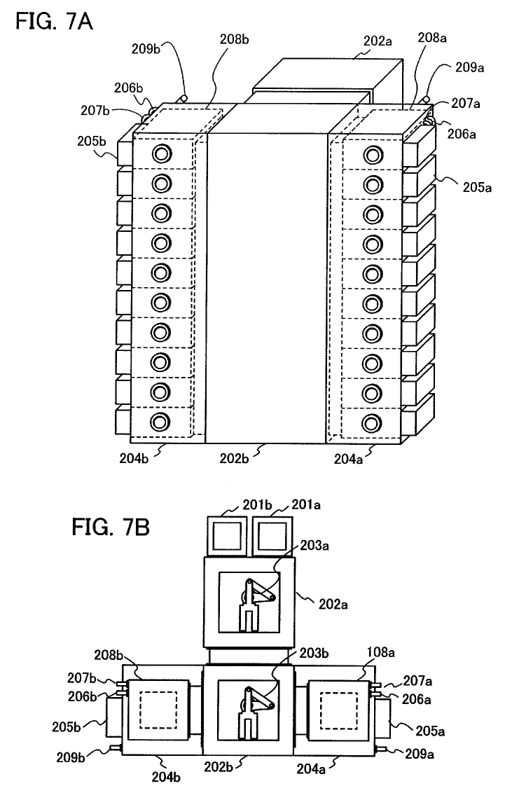

This embodiment mode describes a process of manufacturing a thin film transistor used for a liquid crystal display device with reference to FIGS. 1A to 1D, FIGS. 2A to 2D, FIGS. 3A to 3C, FIG. 4, FIG. 5, FIGS. 6A and 6B, and FIGS. 7A and 7B. FIGS. 1A to 1D, FIGS. 2A to 2D, and FIGS. 3A to 3C are cross-sectional views illustrating a process of manufacturing a thin film transistor. FIG. 4 is a top view of a connection region between a thin film transistor and a pixel electrode in one pixel. Further, FIG. 5 is a timing chart illustrating a method for forming a microcrystalline semiconductor film. FIGS. 6A and 6B illustrate an example of a reaction chamber in which a microcrystalline semiconductor film is formed. FIGS. 7A and 7B are a perspective view and a top view, respectively, of an example of a plasma CVD (chemical vapor deposition) apparatus in which reaction chambers shown in FIG. 6A are stacked vertically.

With regard to a thin film transistor including a microcrystalline semiconductor film, an n-channel thin film transistor has higher mobility than a p-channel thin film transistor; thus, an n-channel thin film transistor is more suitable for a driver circuit. Further, it is preferable that all the thin film transistors formed over one substrate have the same polarity so that the number of manufacturing steps is reduced. In description of this embodiment mode, an n-channel thin film transistor is used.

As illustrated in FIG. 1A, a gate electrode 51 is formed over a substrate 50. As the substrate 50, a non-alkali glass substrate manufactured by a fusion method or a float method, such as a substrate of barium borosilicate glass, aluminoborosilicate glass, or aluminosilicate glass, or the like can be used. When the substrate 50 is mother glass, a first generation (320 mm×400 mm), a second generation (400 mm×500 mm), a third generation (550 mm×650 mm), a fourth generation (680 mm×880 mm or 730 mm×920 mm), a fifth generation (1000 mm×1200 mm or 1100 mm×1250 mm), a sixth generation (1500 mm×1800 mm), a seventh generation (1900 mm×2200 mm), an eighth generation (2160 mm×2460 mm), a ninth generation (2400 mm×2800 mm or 2450 mm×3050 mm), a tenth generation (2950 mm×3400 mm), or the like can be employed for a size of the substrate.

The gate electrode 51 is formed of a metal material such as titanium, molybdenum, chromium, tantalum, tungsten, or aluminum, or an alloy material thereof. The gate electrode 51 can be formed as follows: a conductive film is formed over the substrate 50 by a sputtering method or a vacuum evaporation method; a mask is formed over the conductive film by a photolithography technique or an inkjet method; and the conductive film is etched using the mask. Alternatively, the gate electrode 51 can be formed by discharging a conductive nanopaste of silver, gold, copper, or the like by an inkjet method and baking it. A nitride film of the above metal material may be provided between the substrate 50 and the gate electrode 51 to improve adherence of the gate electrode 51 to the substrate 50. Here, the gate electrode 51 is formed by etching a conductive film formed over the substrate 50 with use of a resist mask formed using a first photomask.

As a specific example of a structure of the gate electrode, a structure in which a molybdenum film is stacked on an aluminum film so that a hillock and electromigration, which are specific phenomena to aluminum, can be prevented may be employed. Further, a three-layer structure in which an aluminum film is sandwiched by molybdenum films may be employed as well. As other examples of the gate electrode structure, a stacked-layer structure in which a molybdenum film is formed on a copper film, a stacked-layer structure in which a titanium nitride film is formed on a copper film, and a stacked-layer structure in which a tantalum nitride film is formed on a copper film can be given.

Since a semiconductor film and a wiring are formed over the gate electrode 51, the gate electrode 51 is preferably processed to have a tapered end portion so that the semiconductor film and the wiring thereover are not disconnected at an edge of the gate electrode 51. Further, although not illustrated, a wiring connected to the gate electrode can also be formed at the same time when the gate electrode is formed.

Subsequently, gate insulating films 52a to 52c are formed in order over the gate electrode 51. FIG. 1A is a cross-sectional view in which the above steps are over.

The gate insulating films 52a to 52c can each be formed by a CVD method, a sputtering method, or the like using a silicon oxide film, a silicon nitride film, a silicon oxynitride film, or a silicon nitride oxide film. In order to prevent an interlayer short-circuit caused by a pinhole or the like formed in the gate insulating film, it is preferable to form plural layers using different insulating layers. Here, a mode is described in which a silicon nitride film, a silicon oxynitride film, and a silicon nitride film are stacked in this order as the gate insulating films 52a, 52b, and 52c, respectively.

Here, note that a silicon oxynitride film means a film that includes more oxygen than nitrogen, and includes oxygen, nitrogen, silicon, and hydrogen at concentrations ranging from 55 at. % to 65 at. %, 1 at. % to 20 at. %, 25 at. % to 35 at. %, and 0.1 at. % to 10 at. %, respectively. Further, a silicon nitride oxide film means a film that includes more nitrogen than oxygen, and includes oxygen, nitrogen, silicon, and hydrogen at concentrations ranging from 15 at. % to 30 at. %, 20 at. % to 35 at. %, 25 at. % to 35 at. %, and 15 at. % to 25 at. %, respectively.

Each of a first layer and a second layer of the gate insulating films is formed to be thicker than 50 nm. It is preferable that the first layer of the gate insulating films be formed of a silicon nitride film or a silicon nitride oxide film in order to prevent diffusion of an impurity (such as alkali metal) from the substrate. Further, the first layer of the gate insulating films can prevent oxidation of the gate electrode and can also prevent hillocks in a case of using aluminum for the gate electrode. A third layer of the gate insulating films that comes into contact with a microcrystalline semiconductor film is formed with a thickness of more than 0 nm and less than or equal to 5 nm, preferably about 1 nm. The third layer of the gate insulating films is provided to improve adhesion with the microcrystalline semiconductor film.

Further, the gate insulating film is preferably formed with use of a plasma CVD apparatus with which microwaves having a frequency of higher than or equal to 1 GHz can be introduced. A silicon oxynitride film or a silicon nitride oxide film formed with use of a microwave plasma CVD apparatus has high withstand voltage, and reliability of a thin film transistor can be enhanced.

Although the gate insulating films employ a three-layer structure here, a single layer of a silicon nitride film may be used in a case where a thin film transistor is used for a switching element of a liquid crystal display device, in which AC driving is performed.

After forming the gate insulating films, it is preferable that the substrate be transferred without being exposed to the atmosphere, and a microcrystalline semiconductor film 53 be formed in a reaction chamber 208a which is different from that for forming the gate insulating films.

A procedure for forming the microcrystalline semiconductor film 53 is described below also with reference to FIG. 5. FIG. 5 shows the procedure starting from a step where vacuum evacuation 100 is performed from atmospheric pressure in the reaction chamber 208a. Then, the following treatments, which are performed after the vacuum evacuation 100, are shown in chronological order: precoating 101, substrate taking-in 102, a base pretreatment 103, a deposition treatment 104, substrate taking-out 105, and cleaning 106. Note that the procedure is not limited to performing vacuum evacuation starting from atmospheric pressure, and it is preferable to maintain the reaction chamber 208a under a certain degree of vacuum at all times in terms of mass production as well as in terms of reducing the ultimate degree of vacuum in a short time.

In this embodiment mode, ultrahigh vacuum evacuation is performed which makes the degree of vacuum lower than 10⁻⁵ Pa in the reaction chamber 208a before taking the substrate into the reaction chamber. This step corresponds to the vacuum evacuation 100 in FIG. 5. In performing such ultrahigh vacuum evacuation, it is preferable to use a turbo-molecular pump and a cryopump; evacuation is performed with the turbo-molecular pump, and vacuum evacuation is performed with the cryopump. It is also effective to connect two turbo-molecular pumps in series and perform vacuum evacuation. Further, it is preferable to provide a heater for baking for the reaction chamber 208a and perform heat treatment to degas the inner wall of the reaction chamber 208a. Further, the temperature is stabilized by operating the heater for heating the substrate. The substrate is heated at temperatures of from 100° C. to 300° C., preferably from 120° C. to 220° C.

In this example, as an apparatus for forming the microcrystalline semiconductor film 53, an apparatus is used in which the atmosphere in a deposition chamber 204a and the reaction chamber 208a becomes continuous when the substrate is transferred from a transfer chamber to the reaction chamber 208a. Specifically, a chamber which can maintain a reduced-pressure atmosphere, i.e., the deposition chamber 204a, is provided for an outside of the reaction chamber 208a. The deposition chamber 204a is designed to be supplied with a sealing gas including hydrogen and/or a rare gas. In this embodiment mode, hydrogen is used as the sealing gas. As the sealing gas, a gas which is highly purified so that the concentration of an element (i.e., an impurity element) except hydrogen and a rare gas can be lower than or equal to 10⁻⁷ at. %, preferably lower than or equal to 10⁻¹⁰ at. %, is used. As an example of a means for lowering the concentration of an impurity element in a hydrogen gas to be lower than or equal to 10⁻⁷ at. %, a method can be given in which the hydrogen gas is purified with use of an ultrahigh-purity hydrogen purifier manufactured by Johnson Matthey plc. or the like. The amount of atmospheric components such as oxygen, nitrogen, and moisture which enter the reaction chamber 208a from the deposition chamber 204a that contains the sealing gas atmosphere is small. If the reaction chamber 208a is provided next to the transfer chamber, when the transfer chamber contains the sealing gas atmosphere as in the deposition chamber 204a, a similar effect can be produced.

In an apparatus with such a structure for forming the microcrystalline semiconductor film 53, the reaction chamber 208a undergoes the precoating 101 to form a silicon film as a film for coating the inner wall of the reaction chamber 208a before taking the substrate into the reaction chamber 208a. In the precoating 101, after removing a gas (an atmospheric component such as oxygen or nitrogen, or an etching gas used in cleaning the reaction chamber 208a) that is attached to the inner wall of the reaction chamber 208a by generating plasma by supplying hydrogen or a rare gas, a silane gas is supplied and plasma is generated. Since a silane gas reacts with oxygen, moisture, and the like, by supplying a silane gas and generating silane plasma, oxygen and moisture in the reaction chamber 208a can be removed. Further, performing the precoating 101 can prevent a metal element of a member constituting the reaction chamber 208a from entering the microcrystalline semiconductor film as an impurity. In other words, covering the inner wall of the reaction chamber 208a with a silicon film can prevent the inner wall of the reaction chamber 208a from being etched by plasma, and can reduce the impurity concentration in the microcrystalline semiconductor film that is formed later. The precoating 101 includes a treatment in which the inner wall of the reaction chamber 208a is covered with a film that is of the same kind as a film to be deposited over the substrate. In the precoating 101, the sealing gas is supplied to the deposition chamber 204a. Here, the pressure in the deposition chamber 204a that has been supplied with the sealing gas is set to be from 0.1 Pa to 100 Pa, approximately.

After the precoating 101, the substrate taking-in 102 is performed. During the substrate taking-in, supply of the sealing gas to the deposition chamber 204a is stopped to improve the degree of vacuum so that the pressures in the transfer chamber and in the reaction chamber 208a do not increase. The substrate over which the microcrystalline semiconductor film is to be deposited is kept in a load chamber that is vacuum-evacuated; therefore, the degree of vacuum in the reaction chamber 208a is not degraded much even when the substrate is taken in. After the substrate taking-in 102, supply of the sealing gas is continued until the substrate taking-out 105.

Next, the base pretreatment 103 is performed. It is preferable that the base pretreatment 103 be performed since it is a treatment that is particularly effective in forming a microcrystalline semiconductor film. In a case of forming a microcrystalline semiconductor film over a glass substrate surface, an insulating film surface, or an amorphous silicon surface by a plasma CVD method, there is a possibility that an amorphous layer is formed at an early stage of deposition due to an impurity or lattice mismatch. In order to reduce the thickness of this amorphous layer as much as possible, or to get rid of it if possible, it is preferable to perform the base pretreatment 103. As the base pretreatment 103, a rare gas plasma treatment, a hydrogen plasma treatment, or a combination of both is preferably performed. For the rare gas plasma treatment, it is preferable that a rare gas element with a large mass number, such as argon, krypton, or xenon, be used in order to remove the impurity such as oxygen, nitrogen, moisture, an organic substance, or a metal element that is attached to the surface by a sputtering effect. The hydrogen plasma treatment is effective in removing the above impurity that is adsorbed to the surface with hydrogen radicals and in forming a clean film formation surface by an etching effect with respect to the insulating film. Further, performing both the rare gas plasma treatment and the hydrogen plasma treatment has an effect of promoting growth of microcrystal nuclei.

In terms of promoting generation of microcrystal nuclei, it is effective to supply a rare gas such as argon continuously at the early stage of forming the microcrystalline semiconductor film, as shown by a broken line 107 in FIG. 5.

Next, the deposition treatment 104 for forming the microcrystalline semiconductor film is performed after the base pretreatment 103. In this embodiment mode, a microcrystalline semiconductor film near an interface with the gate insulating film is formed under the first deposition condition, which is low in deposition rate but results in a good quality film, and then a microcrystalline semiconductor film is deposited under the second deposition condition, which is high in deposition rate.

There are no particular limitations as long as the deposition rate of the second deposition condition is higher than that of the first deposition condition. Therefore, the microcrystalline semiconductor film can be formed by a high-frequency plasma CVD method with a frequency of several tens of MHz to several hundreds of MHz or using a microwave plasma CVD apparatus with a frequency of higher than or equal to 1 GHz; typically, the microcrystalline semiconductor film can be formed by diluting silicon hydride such as SiH₄ or Si₂H₆ with hydrogen and generating plasma. Further, the microcrystalline semiconductor film can be formed using silicon hydride, hydrogen, and one or plural kinds of rare gas elements selected from helium, argon, krypton, and neon. In such a case, a flow ratio of hydrogen to silicon hydride is 12:1 to 1000:1, preferably 50:1 to 200:1, more preferably 100:1. SiH₂Cl₂, SiHCl₃, SiCl₄, SiF₄, or the like can be used instead of silicon hydride.

Further, in the case of adding helium to a source gas, helium has an ionization energy of 24.5 eV, which is the highest among all the gases, and a metastable state thereof lies in a level of 20 eV approximately, which is a little lower than the above ionization energy; thus, to be ionized, helium requires as low as about 4 eV, which is the difference between the ionization energy and the metastable energy, while keeping electric discharge. Therefore, helium starts to discharge electricity at the lowest voltage among all the gases. Because of the above property, helium can stably retain plasma. Further, since uniform plasma can be formed with helium, a plasma density can be uniform even when a microcrystalline semiconductor film is deposited over a large substrate.

Further, an energy band width may be adjusted to from 1.5 eV to 2.4 eV, or from 0.9 eV to 1.1 eV by mixing carbon hydride such as CH₄ or C₂H₆, germanium hydride such as GeH₄, or germanium fluoride such as GeF₄ into a gas such as silane. By adding carbon or germanium to silicon, the temperature characteristic of a TFT can be changed.

Here, under the first deposition condition, silane is diluted greater than 100 times and less than or equal to 2000 times with hydrogen and/or a rare gas, and a heating temperature of the substrate is from 100° C. to 300° C., preferably from 120° C. to 220° C. It is preferable that deposition be preformed at temperatures of from 120° C. to 220° C. in order to inactivate a growing surface of the microcrystalline semiconductor film with hydrogen to promote growth of microcrystalline silicon.

FIG. 1B is a cross-sectional view in which the step of the first deposition condition is over. Over the gate insulating film 52c, a microcrystalline semiconductor film 23 is formed, which is formed with a low deposition rate but has good quality. The quality of this microcrystalline semiconductor film 23 obtained under the first deposition condition contributes to increasing the on current and improving the field effect mobility of a TFT that is completed later; therefore, it is important to sufficiently reduce an oxygen concentration in the film to lower than or equal to 1×10¹⁷/cm³. Further, by the above procedure, not only the concentration of oxygen that mixes into the microcrystalline semiconductor film is reduced, but those of nitrogen and carbon can also be reduced, thereby preventing the microcrystalline semiconductor film from becoming an n-type.

Next, a deposition rate is increased from that under the first deposition condition to that under the second deposition condition, to form the microcrystalline semiconductor film 53. FIG. 1C is a cross-sectional view of this stage. The thickness of the microcrystalline semiconductor film 53 may be from 50 nm to 500 nm (preferably from 100 nm to 250 nm). Note that in this embodiment mode, deposition time of the microcrystalline semiconductor film 53 includes a first deposition period in which deposition is performed under the first deposition condition, and a second deposition period in which deposition is performed under the second deposition condition.

In this embodiment mode, under the second deposition condition, silane is diluted 12 times to 100 times with hydrogen and/or a rare gas, and a heating temperature of the substrate is from 100° C. to 300° C., preferably from 120° C. to 220° C. By reducing the deposition rate, crystallinity tends to improve.

In this embodiment mode, a capacitive coupling (parallel plate) CVD apparatus is used; a gap (a distance between an electrode surface and a substrate surface) is set to be 20 nm; and a microcrystalline semiconductor film is formed under the first deposition condition and the second deposition condition. Under the first deposition condition, a degree of vacuum in the reaction chamber 208a is 100 Pa; a substrate temperature is 100° C.; 30 W of high-frequency power with a frequency of 60 MHz is applied; and a silane gas (a flow rate of 2 sccm) is diluted 200 times with hydrogen (a flow rate of 400 sccm). Under the second deposition condition, the gas flow rate is changed to increase a deposition rate, and a silane gas of 4 sccm is diluted 100 times with hydrogen (a flow rate of 400 sccm). The other conditions are the same as those of the first deposition condition.

Next, after the formation of the microcrystalline semiconductor film under the second deposition condition is completed, supply of the source gas such as silane and hydrogen, and of the high-frequency power is stopped, and the substrate taking-out 105 is performed. In a case of performing deposition treatment to a subsequent substrate, the same treatments starting from the substrate taking-in 102 are performed.

After that, the cleaning 106 is performed if a deposited film or powder on the inner wall of the reaction chamber 208a is removed. For the cleaning 106, an etching gas typified by NF₃ or SF₆ is supplied and plasma etching is performed. Alternatively, a gas such as ClF₃ with which etching can be performed without plasma is supplied. It is preferable to turn off the heater for heating the substrate and to reduce the temperature in the cleaning 106 in order to suppress generation of a reaction by-product of etching. After the cleaning 106, the ultimate pressure in the reaction chamber 208a is reduced to from 1×10⁻⁸ to 1×10⁻⁵ Pa approximately; a gas which is unnecessary for forming a subsequent film is discharged; and the process may return to the precoating 101 to perform treatments similar to the above to a subsequent substrate.

Next, after forming the microcrystalline semiconductor film 53, the substrate is transferred without being exposed to the atmosphere, and a buffer layer 54 is preferably formed in a different reaction chamber from the reaction chamber 208a for forming the microcrystalline semiconductor film 53. The microcrystalline semiconductor film 53 and the buffer layer 54 are formed in their respective reaction chambers, whereby the inside of the reaction chamber 208a for forming the microcrystalline semiconductor film 53 can be placed in an ultrahigh vacuum before taking in the substrate; impurity contamination can be suppressed as much as possible; and the time it takes to attain the ultrahigh vacuum can be shortened. This is particularly effective in a case of performing baking to attain the ultrahigh vacuum because it takes time to lower and stabilize the inner-wall temperature of the reaction chamber 208a. Furthermore, by having separate reaction chambers, different frequencies of high-frequency power can be used according to the film quality that is to be obtained.

The buffer layer 54 is formed using an amorphous semiconductor film including hydrogen, nitrogen, or halogen. An amorphous semiconductor film including hydrogen can be formed using hydrogen with a flow rate that is 1 time to 10 times, preferably 1 time to 5 times that of silicon hydride. Further, an amorphous semiconductor film including nitrogen can also be formed using the above silicon hydride, and nitrogen or ammonia. Furthermore, an amorphous semiconductor film including fluorine or chlorine can also be formed using above the silicon hydride, and a gas including fluorine or chlorine (e.g., F₂, Cl₂, HF, or HCl). SiH₂Cl₂, SiHCl₃, SiC₄, SiF₄, or the like can be used instead of silicon hydride.

Further, as the buffer layer 54, an amorphous semiconductor film can be formed by sputtering an amorphous semiconductor, which is a target, with hydrogen or a rare gas. At this time, if ammonia, nitrogen, or N₂O is included in the atmosphere, an amorphous semiconductor film including nitrogen can be formed. If a gas including fluorine or chlorine (e.g., F₂, Cl₂, HF, or HCl) is included in the atmosphere, an amorphous semiconductor film including fluorine or chlorine can be formed.

It is preferable to form the buffer layer 54 using an amorphous semiconductor film which does not include a crystal grain. Therefore, if the buffer layer 54 is formed by a high-frequency plasma CVD method with a frequency of several tens of MHz to several hundreds of MHz, or a microwave plasma CVD method, it is preferable to control the film deposition condition so that the buffer layer 54 may be an amorphous semiconductor film that does not include a crystal grain.

In a later process of forming a source region and a drain region, a part of the buffer layer 54 is etched. It is preferable to form the buffer layer 54 with such a thickness that the part of the buffer layer 54 can remain at that time so that the microcrystalline semiconductor film 53 is not exposed. Typically, it is preferable to form the buffer layer 54 with a thickness of from 30 nm to 400 nm inclusive, preferably from 40 nm to 300 nm inclusive. In a display device including a thin film transistor to which high voltage (e.g., about 15 V) is applied, typically in a liquid crystal display device, if the buffer layer 54 is formed to have a large thickness as shown above, resistance of the drain to voltage is increased; thus, deterioration of the thin film transistor can be prevented even when high voltage is applied to the thin film transistor.

An impurity element imparting one conductivity type, such as phosphorus or boron, is not added to the buffer layer 54. The buffer layer 54 functions as a barrier layer so that an impurity element from a semiconductor film 55 to which an impurity element imparting one conductivity type is added is not dispersed into the microcrystalline semiconductor film 53. It is also possible not to provide the buffer layer; however, if the microcrystalline semiconductor film 53 and the semiconductor film 55 to which the impurity element imparting one conductivity type is added come into contact with each other, the impurity element moves in a later etching step or heat treatment, and there is a possibility that control of a threshold voltage becomes difficult.

Further, by forming the buffer layer 54 over the surface of the microcrystalline semiconductor film 53, natural oxidation of surfaces of crystal grains included in the microcrystalline semiconductor film 53 can be prevented. In particular, in a region where an amorphous semiconductor is in contact with microcrystal grains, a crack is likely to be caused because of local stress. When this crack is exposed to oxygen, the crystal grains are oxidized to form silicon oxide.

The buffer layer 54, which is an amorphous semiconductor film, has a larger energy gap than the microcrystalline semiconductor film 53 (an energy gap of the amorphous semiconductor film is from 1.6 eV to 1.8 eV, whereas that of the microcrystalline semiconductor film 53 is from 1.1 eV to 1.5 eV), higher resistance, and as low mobility as ⅕ to 1/10 that of the microcrystalline semiconductor film 53. Thus, in the thin film transistor that is completed later, the buffer layer formed between the source and drain regions and the microcrystalline semiconductor film 53 functions as a high resistant region, and the microcrystalline semiconductor film 53 functions as a channel formation region. Therefore, off current of the thin film transistor can be reduced. If the thin film transistor is used as a switching element of a display device, the display device can have an improved contrast.

It is preferable to form the buffer layer 54 at temperatures of from 300° C. to 400° C. over the microcrystalline semiconductor film 53 by a plasma CVD method. This deposition treatment supplies hydrogen to the microcrystalline semiconductor film 53, thereby producing the same effect as hydrogenation treatment for the microcrystalline semiconductor film 53. That is to say, depositing the buffer layer 54 over the microcrystalline semiconductor film 53 can disperse hydrogen into the microcrystalline semiconductor film 53, thereby terminating a dangling bond.

Next, after forming the buffer layer 54, the substrate is transferred without being exposed to the atmosphere, and the semiconductor film 55 to which the impurity element imparting one conductivity type is added is preferably formed in a different reaction chamber from the reaction chamber for forming the buffer layer 54. FIG. 1D is a cross-sectional view at this stage. The buffer layer 54 and the semiconductor film 55 to which the impurity element imparting one conductivity type is added are formed in their respective reaction chambers, thereby preventing the impurity element imparting one conductivity type from mixing into the buffer layer when the buffer layer 54 is formed.

If an n-channel thin film transistor is formed, the semiconductor film 55 to which the impurity element imparting one conductivity type is added may be doped with phosphorus, which is a typical impurity element; for example, an impurity gas such as a phosphine gas (PH₃) may be added to silicon hydride. If a p-channel thin film transistor is formed, the semiconductor film 55 to which the impurity element imparting one conductivity type is added may be doped with boron, which is a typical impurity element; for example, an impurity gas such as B₂H₆ may be added to silicon hydride. The semiconductor film 55 to which the impurity element imparting one conductivity type is added can be formed using a microcrystalline semiconductor or an amorphous semiconductor. The semiconductor film 55 to which the impurity element imparting one conductivity type is added has a thickness of from 2 nm to 50 nm. By forming the semiconductor film to which the impurity element imparting one conductivity type is added with a small thickness, throughput can be improved.

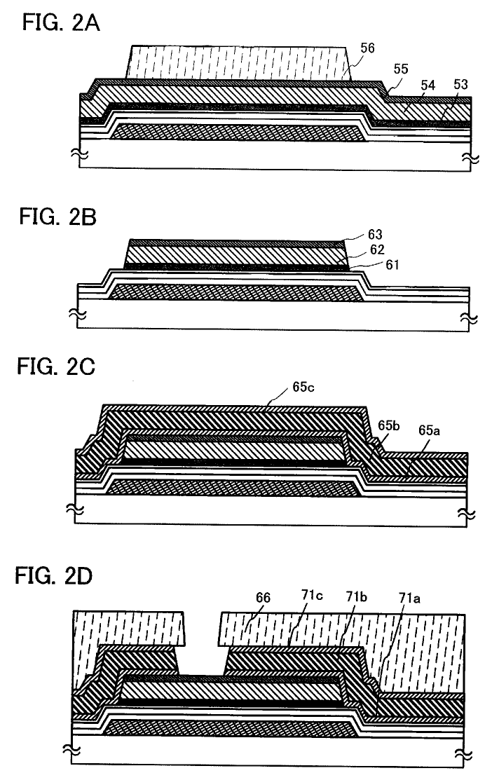

Next, as shown in FIG. 2A, a resist mask 56 is formed over the semiconductor film 55 to which the impurity element imparting one conductivity type is added. The resist mask 56 is formed by a photolithography technique or an inkjet method. Here, using a second photomask, the resist mask 56 is formed by exposing a resist that is applied over the semiconductor film 55 to which the impurity element imparting one conductivity type is added, to light and developing the resist.

Next, the microcrystalline semiconductor film 53, the buffer layer 54, and the semiconductor film 55 to which the impurity element imparting one conductivity is added are etched using the resist mask 56, to form a microcrystalline semiconductor film 61, a buffer layer 62, and a semiconductor film 63 to which the impurity element imparting one conductivity type is added, as shown in FIG. 2B. After that, the resist mask 56 is removed.

The microcrystalline semiconductor film 61 and the buffer layer 62 have inclined end side portions, whereby the source and drain regions, which are formed over the buffer layer 62, and the microcrystalline semiconductor film 61 can have a longer distance therebetween, and thus leakage current can be prevented. Further, leakage current which is generated between source and drain electrodes and the microcrystalline semiconductor film 61 can be prevented. An inclination angle of the end side portions of the microcrystalline semiconductor film 61 and the buffer layer 62 is from 30° to 90°, preferably 45° to 80°. The end side portions with such an angle can prevent the source electrode or the drain electrode from being disconnected owing to a step form.

Next, as shown in FIG. 2C, conductive films 65a to 65c are formed so as to cover the semiconductor film 63 to which the impurity element imparting one conductivity type is added and the gate insulating film 52c. The conductive films 65a to 65c are preferably formed with a single layer or stacked layers using aluminum; copper; or an aluminum alloy to which an element for preventing migration, an element for improving heat resistance property, or an element for preventing hillocks, such as copper, silicon, titanium, neodymium, scandium, or molybdenum, is added. Alternatively, a film in contact with the semiconductor film to which the impurity element imparting one conductivity type is added may be formed of titanium, tantalum, molybdenum, or tungsten, or nitride of such an element; and aluminum or an aluminum alloy may be formed thereover to form a stacked-layer structure. Further alternatively, top and bottom surfaces of aluminum or an aluminum alloy may be each covered with titanium, tantalum, molybdenum, tungsten, or nitride thereof to form a stacked-layer structure. This embodiment mode shows the conductive film having a three-layer structure of the conductive films 65a to 65c; a stacked-layer structure in which the conductive films 65a and 65c are formed using molybdenum films and the conductive film 65b is formed using an aluminum film, or a stacked-layer structure in which the conductive films 65a and 65c are formed using titanium films and the conductive film 65b is formed using an aluminum film is formed. The conductive films 65a to 65c are formed by a sputtering method or a vacuum evaporation method.

Next, as shown in FIG. 2D, a resist mask 66 is formed over the conductive films 65a to 65c using a third photomask, and the conductive films 65a to 65c are partly etched to form pairs of source and drain electrodes 71a to 71c. By wet-etching the conductive films 65a to 65c, the conductive films 65a to 65c are etched isotropically. Consequently, the source and drain electrodes 71a to 71c with a smaller area than that of the resist mask 66 can be formed.

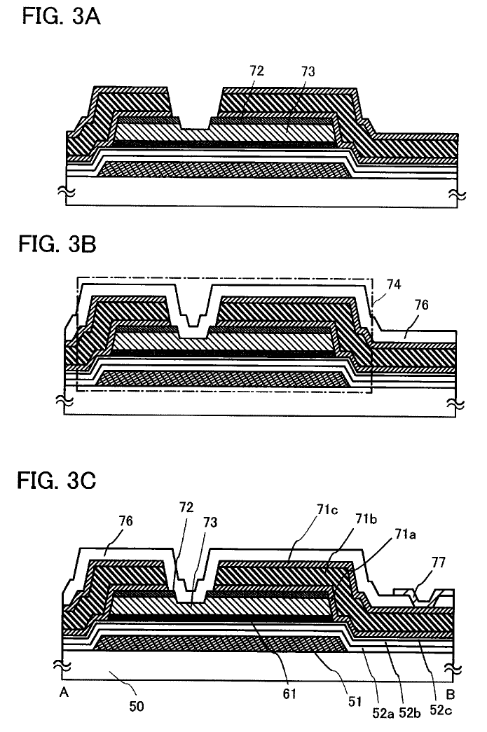

Next, as shown in FIG. 3A, the semiconductor film 63 to which the impurity element imparting one conductivity type is added is etched using the resist mask 66, to form a pair of source and drain regions 72. In this etching step, further, a part of the buffer layer 62 is also etched. The buffer layer which is etched partly and has a recessed portion is referred to as a buffer layer 73. The source and drain regions and the recessed portion of the buffer layer can be formed in the same step. The recessed portion of the buffer layer is formed with a depth which is ½ to ⅓ of the largest thicknesses of the buffer layer, so that the source and drain regions can be separated from each other with a longer distance therebetween; thus, leakage current between the source and drain regions can be reduced. After that, the resist mask 66 is removed.

When a resist mask is exposed to plasma used in dry etching or the like, the resist mask changes in quality and is not removed completely in a resist removal step. Accordingly, the buffer layer is etched by about 50 nm in order to prevent residues from remaining. The resist mask 66 is used twice, once in the treatment for partly etching the portion of the conductive films 65a to 65c, and once in the etching treatment for forming the source and drain regions 72. When dry etching is used in both treatments, residues are likely to remain; therefore, it is effective to form the buffer layer with a large thickness which allows for extra etching, in removing residues completely. In addition, the buffer layer 73 can prevent plasma damage to the microcrystalline semiconductor film 61 in dry etching.

Next, as shown in FIG. 3B, an insulating film 76 is formed to cover the source and drain electrodes 71a to 71c, the source and drain regions 72, the buffer layer 73, the microcrystalline semiconductor film 61, and the gate insulating film 52c. The insulating film 76 can be formed using the same method as that used for forming the gate insulating films 52a to 52c. The insulating film 76 is provided to prevent contamination impurities such as organic substances, metals, or moisture included in the atmosphere from entering, and is preferably a dense film. By forming the insulating film 76 using a silicon nitride film, the oxygen concentration in the buffer layer 73 can be reduced to lower than or equal to 5×10¹⁹ atoms/cm³, preferably lower than or equal to 1×10¹⁹ atoms/cm³.

As shown in FIG. 3B, the end portions of the source and drain electrodes 71a to 71c are not aligned with those of the source and drain regions 72, whereby the distance between the end portions of the source and drain electrodes 71a to 71c can be long; thus, leakage current or short circuit between the source and drain electrodes can be prevented. Accordingly, a thin film transistor with high reliability and high withstand voltage can be manufactured.

Through the above process, a thin film transistor 74 can be formed.

In the thin film transistor described in this embodiment mode, the gate insulating film, the microcrystalline semiconductor film, the buffer layer, the source and drain regions, and the source and drain electrodes are stacked over the gate electrode, and the buffer layer covers the surface of the microcrystalline semiconductor film, which functions as a channel formation region. In addition, the recessed portion is formed in part of the buffer layer, and regions other than the recessed portion are covered with the source and drain regions. That is, since there is a long distance between the source region and the drain region due to the recessed portion formed in the buffer layer, leakage current between the source and drain regions can be reduced. In addition, since the recessed portion is formed by etching the part of the buffer layer, etching residues which are caused in the step of forming the source and drain regions can be removed. Accordingly, generation of leakage current (parasitic channel) which is due to residues can be prevented between the source and drain regions.

Further, the buffer layer is formed between the microcrystalline semiconductor film, which functions as a channel formation region, and the source and drain regions. Furthermore, the buffer layer covers the surface of the microcrystalline semiconductor film. Since the buffer layer, which has high resistance, is formed between the microcrystalline semiconductor film and the source and drain regions, generation of leakage current can be reduced in the thin film transistor, and deterioration due to application of high voltage can be suppressed. In addition, the buffer layer, the microcrystalline semiconductor film, and the source and drain regions are formed in a region that overlaps with the gate electrode. Accordingly, a structure thereof is not affected by a shape of an end portion of the gate electrode. When the gate electrode is formed with a stacked-layer structure and aluminum is used in a lower layer, there is a possibility of generation of a hillock due to aluminum exposed on a side surface of the gate electrode. However, a structure in which the source and drain regions do not overlap with the end portions of the gate electrode can prevent short circuit in a region overlapping with the side surface of the gate electrode. Moreover, since the amorphous semiconductor film whose surface is subjected to termination by hydrogen is formed as the buffer layer over the surface of the microcrystalline semiconductor film, oxidation of the microcrystalline semiconductor film can be prevented, and entrance of etching residues which are caused in the step of forming the source and drain regions into the microcrystalline semiconductor film can be prevented. Accordingly, the thin film transistor has high electric characteristics and high withstand voltage.

Further, since the channel formation region is formed of a microcrystalline semiconductor film, the channel formation region has a higher carrier density than a channel formation region formed of an amorphous semiconductor film; thus, the channel width of the thin film transistor can be reduced and the planar area of the thin film transistor can be reduced.

Next, a contact hole is formed in the insulating film 76 by etching a part of the insulating film 76 using a resist mask that is formed using a fourth photomask. Then, a pixel electrode 77 is formed in the contact hole, to be in contact with the source or drain electrode 71c. FIG. 3C is a cross-sectional view taken along a chain line A-B in FIG. 4.

As shown in FIG. 4, the end portions of the source and drain regions 72 are located at outer side than those of the source and drain electrodes 71c. Further, the end portion of the buffer layer 73 is located at outer side than those of the source and drain electrodes 71c and those of the source and drain regions 72. Furthermore, one of the source and the drain electrodes surrounds the other source or drain electrode (specifically, the former electrode is in a U-shape or a C-shape). Therefore, the area of a region where carriers travel can be increased; thus, the amount of current can be increased, and the area of the thin film transistor can be reduced. Further, the microcrystalline semiconductor film and the source and drain electrodes overlap with each other over the gate electrode; thus, influence by unevenness of the microcrystalline semiconductor film formed over the gate electrode is small and reduction in coverage and generation of a leakage current can be suppressed. Either the source electrode or the drain electrode also functions as a source wiring or a drain wiring.

The pixel electrode 77 can be formed using a light-transmitting conductive material such as indium oxide including tungsten oxide, indium zinc oxide including tungsten oxide, indium oxide including titanium oxide, indium tin oxide including titanium oxide, indium tin oxide, indium zinc oxide, or indium tin oxide to which silicon oxide is added.

Further, the pixel electrode 77 can be formed using a conductive composition including a conductive high molecule (also referred to as a conductive polymer). It is preferable that a pixel electrode formed using a conductive composition have sheet resistance of less than or equal to 10000 Ω/square, and light transmittance of greater than or equal to 70% at a wavelength of 550 nm. Further, it is preferable that a conductive high molecule included in a conductive composition have resistivity of less than or equal to 0.1 Ω·cm.

As a conductive high molecule, a “π electron conjugated conductive high molecule” can be used. For example, polyaniline or a derivative thereof, polypyrrole or a derivative thereof, polythiophene or a derivative thereof, or a copolymer of two or more kinds of these materials can be given.

In this example, to form the pixel electrode 77, an indium tin oxide film is formed by a sputtering method, and then a resist is applied to the indium tin oxide film. Subsequently, the resist is exposed to light and developed using a fifth photomask, thereby forming a resist mask. Then, the indium tin oxide film is etched using the resist mask to form the pixel electrode 77.

In the above manner, an element substrate which can be used for a display device can be formed.

### Embodiment Mode 2

This embodiment mode shows an example of a multi-chamber plasma CVD apparatus suitable for forming the microcrystalline semiconductor film included in the TFT described in Embodiment Mode 1.

FIG. 6A shows an example of a plasma CVD apparatus in which a chamber which can keep a reduced-pressure atmosphere, i.e., the deposition chamber 204a, is provided for an outside of the reaction chamber 208a for forming the microcrystalline semiconductor film 53, which is shown in Embodiment Mode 1.

In FIG. 6A, the reaction chamber 208a is grounded in this example. A reference numeral 205a designates a high-frequency power supply. A reference numeral 221 designates a first electrode (an upper electrode, a shower electrode, or a high-frequency electrode) which has a hollow structure and through which a source gas can pass. A reference numeral 225 designates a second electrode (a lower electrode or a grounded electrode) which is grounded. A reference numeral 206a designates a supply system for the reaction chamber. A reference numeral 207a designates an exhaust system for the reaction chamber. Reference numerals 206c and 207c designate valves for the reaction chamber. In FIGS. 6A and 6B, further, a heater 226 is provided for an outer wall of the reaction chamber, thereby obtaining a hot wall structure in the reaction chamber. Alternatively, the heater may be provided for the first electrode 221. A gas which is necessary for forming the microcrystalline semiconductor film 53 is supplied from the supply system 206a for the reaction chamber.

A reference numeral 209a designates a supply system for the deposition chamber. A reference numeral 209c designates a valve for the deposition chamber. Although an exhaust system for the deposition chamber is also provided, it is not illustrated. A sealing gas is supplied from the supply system for the deposition chamber.

A side face of the reaction chamber is provided with a window (not illustrated). By opening and closing this window, a substrate can be transferred into the reaction chamber from a cassette chamber which houses the substrate, using a transfer mechanism such as a robot arm.

As described in Embodiment Mode 1, a process of forming a microcrystalline semiconductor film is as follows: after precoating, a substrate is taken into the reaction chamber; then, a power supply switch 222 is turned on to apply a high-frequency voltage to the electrodes, so that plasma 223 is generated; chemically active excited species such as ions or radicals which are generated in this plasma react with each other, so that a microcrystalline semiconductor film 224, which is a product of the reaction, is formed. After the base pretreatment, a microcrystalline semiconductor film is formed on the first electrode 221, the second electrode 225, and a substrate 227 to be treated in the chamber, through the deposition process.

FIG. 6B is a schematic diagram which shows a gas flow when a sealing gas is supplied into the deposition chamber 204a. Part of a sealing gas 231 in the deposition chamber 204a flows into the reaction chamber 208a through a gap in a wall of the reaction chamber 208a or the like. Further, a gas also flows in a reverse direction. A gap in a wall of the reaction chamber 208a or the like is very small, and a gas flow 232 at this time is a viscous flow. That is, a gas that flows from the deposition chamber 204a into the reaction chamber 208a mainly contains a component of the sealing gas 231.

Also through a gap in a wall of the deposition chamber or the like, there arises a gas flow 233 from the atmosphere into the deposition chamber, and oxygen, nitrogen, H₂O, and the like flow into the deposition chamber because of the same principle as the above. The flow rate of the sealing gas and the pressure in the deposition chamber are determined also with the influence of the gas flow 233 taken into account.

FIG. 7A is a perspective view of an example of a plasma CVD apparatus in which reaction chambers shown in FIG. 6A are stacked vertically. FIG. 7B is a top view thereof.

The deposition apparatus shown in FIGS. 7A and 7B includes deposition chambers and transfer chambers. A transfer chamber 202b is provided between deposition chambers 204a and 204b, and transfer chambers 202a and 202b are provided to be adjacent to each other. The deposition chambers 204a and 204b include ten reaction chambers 208a and ten reaction chambers 208b, respectively, which are stacked vertically. The reaction chambers 208a and 208a are provided with supply systems 206a and 206b for supplying a deposition gas, exhaust systems 207a and 207b for exhausting an exhaust gas, and power supplies 205a and 205b, respectively.

This apparatus has a feature that in each of the deposition chambers 204a and 204b, all of the supply systems of the plurality of reaction chambers 208a are connected to one supply source and all of the supply systems of the plurality of reaction chambers 208b are connected to one supply source. Similarly, another feature is that all of the exhaust systems of the plurality of reaction chambers 208a are connected to one exhaust port and all of the exhaust systems of the plurality of reaction chambers 208b are connected to one exhaust port. Although the plurality of reaction chambers 208a and 208b are stacked vertically in this apparatus, the supply systems 206a and 206b and the exhaust systems 207a and 207b can be easily provided owing to the above features. Further, the deposition chambers 204a and 204b are provided with exhaust systems (not illustrated) for reducing pressure in each deposition chamber, and with supply systems 209a and 209b for supplying a sealing gas. Controlling the pressures in the reaction chambers and in the deposition chambers makes it possible to perform deposition and cleaning alternately in the reaction chambers, so that films can be formed efficiently.

In FIG. 7B, substrates which have desired sizes and insulating surfaces, and are typified by a glass substrate or a resin substrate (e.g., a plastic substrate) are set in cassette chambers 201a and 201b. Although substrates are transferred horizontally in the apparatus illustrated, in a case of using substrates meters square, which are a fifth generation or later, the substrates may be disposed vertically and may be transferred vertically in order to reduce the area of the transfer mechanism.

The transfer chambers 202a and 202b are provided with transfer mechanisms (robot arms) 203a and 203b, respectively. The substrates that are set in the cassette chambers 201a and 201b are transferred to the deposition chambers 204a and 204b, respectively, using the transfer mechanisms. Then, surfaces to be treated of the transferred substrates undergo given treatment in the reaction chambers 208a and 208b of the deposition chambers 204a and 204b. Although a plurality of transfer chambers are provided in FIG. 7B, the number thereof may be one. Further, although not illustrated, a supply system for supplying a sealing gas may be provided for the transfer chamber.

Although this embodiment mode presents an example of a batch apparatus, in which several tens of substrates are treated simultaneously, the present invention can also be applied to a single-wafer apparatus, in which substrates are treated one by one. In either case, note that a reaction chamber is provided in a deposition chamber in which a reduced-pressure atmosphere can be made, and a supply system for supplying a sealing gas is provided for the deposition chamber.

As shown in FIG. 7A, with the use of the deposition apparatus having the plurality of reaction chambers, films can be formed over a plurality of substrates under a same condition. Thus, variations among substrates can be reduced and a yield can be improved. Further, a throughput can be improved.

Further, if an additional deposition chamber is provided in addition to the deposition chambers 204a and 204b that are connected to the transfer chamber 202b in FIG. 7A and a gate insulating film is formed in a reaction chamber in the additional deposition chamber in a similar manner to the above, the substrate can be transferred and the gate insulating film and the microcrystalline semiconductor film can be formed successively without being exposed to the atmosphere.

### Embodiment Mode 3

This embodiment mode describes a method for manufacturing a thin film transistor with excellent characteristics by a method for selecting a gas used for depositing a microcrystalline semiconductor film by a CVD method, and by a deposition method.

In a method, the microcrystalline semiconductor film 23 obtained under the first deposition condition in Embodiment Mode 1 is made to have n-type conductivity, thereby improving field effect mobility of the TFT. Specifically, an n-type impurity element is added in forming the microcrystalline semiconductor film under the first deposition condition. As the n-type impurity element used at this time, phosphorus, arsenic, or antimony can be used. In particular, it is preferable to use phosphorus, which is available in a form of phosphine gas at a low price.

Further, by exposing a surface of the gate insulating film to a slight amount of phosphine gas, phosphorus attaches to (or reacts with) the surface of the gate insulating film before nitrogen or oxygen attaches thereto (or reacts therewith), which prevents the microcrystalline semiconductor film 23 at or near the interface with the gate insulating film from taking in much nitrogen or oxygen.

As an atmosphere including a slight amount of phosphine gas, a mixed gas atmosphere of a phosphine gas and an inert gas (e.g., argon gas), a mixed gas atmosphere of a silane gas and a phosphine gas, a mixed gas atmosphere of a silane gas diluted with hydrogen, and a phosphine gas, or the like can be used. In particular, the mixed gas atmosphere including both a silane gas and a phosphine gas can effectively reduce nitrogen or oxygen which is taken in the microcrystalline semiconductor film 23 at or near the interface with the gate insulating film.

Further, not only are a silane gas and a phosphine gas supplied into a chamber before forming the microcrystalline semiconductor film 23, but plasma may also be generated to form the microcrystalline semiconductor film on the inner wall of the reaction chamber. If the microcrystalline semiconductor film including phosphorus is formed on the inner wall of the reaction chamber and then a substrate is taken into the reaction chamber and the microcrystalline semiconductor film 23 is formed, phosphorus can be included in the microcrystalline semiconductor film 23 at an early stage of deposition. Further, also by forming the microcrystalline semiconductor film including phosphorus on the inner wall of the reaction chamber before taking in a substrate and forming the gate insulating film and the microcrystalline semiconductor film 23, phosphorus can be included in the microcrystalline semiconductor film 23 at an early stage of deposition.

Furthermore, the microcrystalline semiconductor film 23 may also be formed in the following manner: plasma is generated using a mixed gas, as a source gas, in which a slight amount of phosphine gas is mixed in a silane gas diluted with hydrogen, with the flow rate of each gas controlled, to form the microcrystalline semiconductor film 23 which is made to have n-type conductivity; then, supply of the slight amount of phosphine gas is stopped; subsequently, the microcrystalline semiconductor film 23 is deposited using a silane gas diluted with hydrogen. If this method is employed, the phosphorus concentration in the microcrystalline semiconductor film 23 which is made to have n-type conductivity is made to be distributed uniformly or substantially uniformly. Further, the phosphorus concentration may be controlled so that a concentration peak can be present near the gate insulating film by changing the flow rate of a phosphine gas stepwise to form a concentration gradient in the phosphorus concentration in the microcrystalline semiconductor film 23 which is made to have n-type conductivity.

At this time, the phosphorus concentration in the microcrystalline semiconductor film 23 is set to be from 6×10¹⁵/cm³ to 3×10¹⁸/cm³ inclusive, preferably from 3×10¹⁶/cm³ to 3×10¹⁷/cm³ inclusive.

Although an example is shown above in which a phosphine gas is used during formation of the microcrystalline semiconductor film 23, as another example in which an n-type impurity element is added to the microcrystalline semiconductor film 23, it is also effective to supply a phosphine gas into the reaction chamber for forming the microcrystalline semiconductor film 23 only before taking in the substrate.

That is, after hydrogen or a rare gas is supplied into the reaction chamber and plasma is generated to remove a gas (atmospheric components such as oxygen and nitrogen, or an etching gas used to clean the reaction chamber) attaching to the inner wall of the reaction chamber, hydrogen, a silane gas, and a slight amount of phosphine gas are supplied into the reaction chamber. The silane gas can react with oxygen, moisture, and the like in the reaction chamber. With the slight amount of phosphine gas, phosphorus can be included in the microcrystalline semiconductor film 23 that is deposited later.

Subsequently, the substrate is taken into the reaction chamber and the microcrystalline semiconductor film 23 as shown in Embodiment Mode 1 is formed, whereby phosphorus can be included in the microcrystalline semiconductor film 23 near the interface with the gate insulating film to make the microcrystalline semiconductor film 23 have n-type conductivity. In a practical case, the phosphorus concentration in the microcrystalline semiconductor film decreases as the distance from the interface with the gate insulating film increases.

In the above manner, by making the microcrystalline semiconductor film 23 have n-type conductivity, the field effect mobility of a TFT can be improved.

### Embodiment Mode 4

This embodiment mode presents a method for enhancing the crystallinity of the microcrystalline semiconductor film 23 formed according to the present invention.

In a treatment method for enhancing the crystallinity of the microcrystalline semiconductor film 23, a surface of the microcrystalline semiconductor film 23 is treated with glow discharge plasma with the use of fluorine or a gas including fluorine (typically, fluoride of hydrogen, silicon, germanium, or the like), which is a silane fluoride gas in this example. At this time, fluorine radicals are generated from silane fluoride with the glow discharge plasma. Fluorine radicals, which are highly reactive, selectively etch an amorphous semiconductor, which is etched more easily than a microcrystalline semiconductor.

In another treatment method, a silane fluoride gas is added to the gas supplied in depositing the microcrystalline semiconductor film 23. At this time, in depositing the microcrystalline semiconductor film 23, the deposition proceeds while an amorphous semiconductor, which is easily etched, is etched selectively with fluorine radicals. Thus, a microcrystalline semiconductor after the deposition has high crystallinity.

These treatment methods for enhancing crystallinity are effective not only in forming the microcrystalline semiconductor film 23 but also in forming the microcrystalline semiconductor film 53 by changing the first deposition condition to the second deposition condition shown in Embodiment Mode 1 by increasing the deposition rate. Further, the treatment methods for enhancing crystallinity are also effective in changing the first deposition condition to the second deposition condition gradually.

Furthermore, it is also effective to supply a silane fluoride gas into the reaction chamber before taking the substrate in the reaction chamber to form the microcrystalline semiconductor film 23. At this time, before taking the substrate into the reaction chamber, a gas including a silane fluoride gas is supplied and plasma is generated, so that fluorine or a fluorine compound remains as a gas in the reaction chamber or attaches to the inner wall of the reaction chamber; thus, the remaining fluorine or fluorine compound acts on the microcrystalline semiconductor film 23 that is formed after taking the substrate into the reaction chamber, whereby crystallinity of the microcrystalline semiconductor film 23 can be enhanced.

This embodiment mode can be combined with Embodiment Mode 1, and further with Embodiment Mode 3 as appropriate.

### Embodiment Mode 5

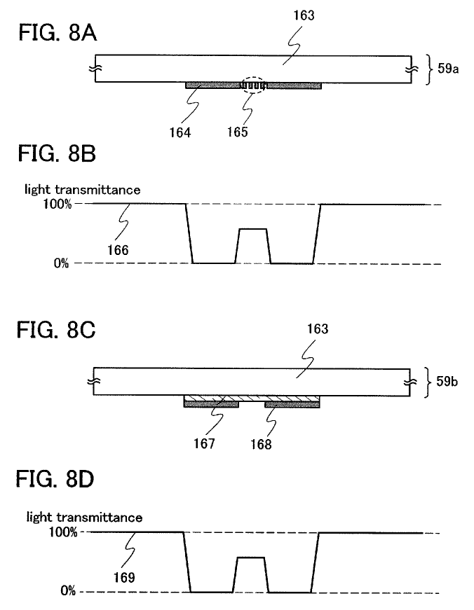

A method for manufacturing a thin film transistor which is different from that in Embodiment Mode 1 is described with reference to FIGS. 8A to 8D, FIGS. 9A and 9B, FIGS. 10A to 10C, FIGS. 11A and 11B, and FIGS. 12A to 12C. This embodiment mode describes a process for manufacturing a thin film transistor in which the number of photomasks can be reduced compared to Embodiment Mode 1.

In a similar manner to FIG. 1A described in Embodiment Mode 1, a conductive film is formed over a substrate 50; a resist is applied over the conductive film; and the conductive film is partly etched using a resist mask formed by a photolithography process using a first photomask, so that a gate electrode 51 is formed. Next, gate insulating films 52a to 52c are formed in this order over the gate electrode 51.

Next, in a similar manner to FIG. 1B described in Embodiment Mode 1, a microcrystalline semiconductor film 23 is formed under the first deposition condition. Then, in a similar manner to FIG. 1C described in Embodiment Mode 1, a microcrystalline semiconductor film 53 is formed in the same reaction chamber under the second deposition condition. Next, in a similar manner to FIG. 1D described in Embodiment Mode 1, a buffer layer 54 and a semiconductor film 55 to which an impurity element imparting one conductivity type is added are formed in this order over the microcrystalline semiconductor film 53.

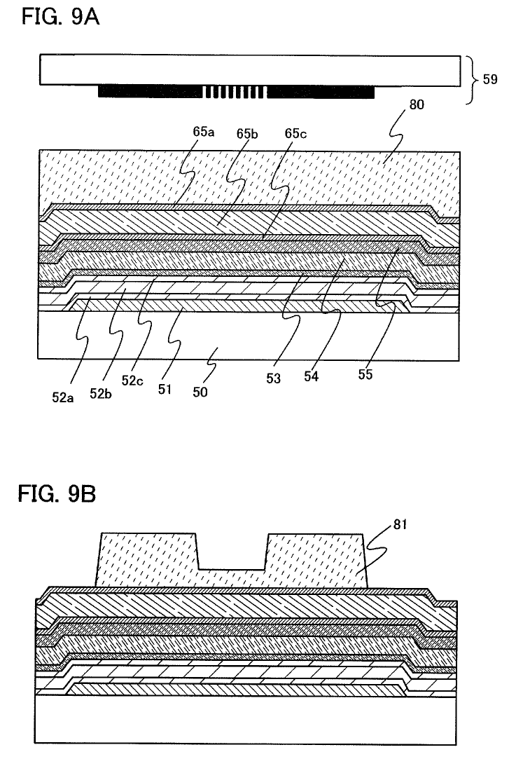

Next, conductive films 65a to 65c are formed over the semiconductor film 55 to which the impurity element imparting one conductivity type is added. Subsequently, as shown in FIG. 9A, a resist 80 is applied over the conductive film 65a.

The resist 80 can be a positive type or a negative type. In this embodiment mode, a positive resist is used as the resist 80.

Next, the resist 80 is irradiated with light using a multi-tone photomask 59 as a second photomask, to expose the resist 80 to light.

Next, light exposure using the multi-tone photomask 59 is described with reference to FIGS. 8A to 8D.

A multi-tone photomask can achieve three levels of light exposure to obtain an exposed portion, a half-exposed portion, and an unexposed portion; one-time exposure and development process allows a resist mask with regions of plural thicknesses (typically, two kinds of thicknesses) to be formed. Thus, a multi-tone photomask can reduce the number of photomasks.

Typical examples of a multi-tone photomask include a gray-tone mask 59a as shown in FIG. 8A, and a half-tone mask 59b as shown in FIG. 8C.

As shown in FIG. 8A, the gray-tone mask 59a includes a light-transmitting substrate 163 provided with a light-blocking portion 164 and a diffraction grating 165. The light transmittance of the light-blocking portion 164 is 0%. The diffraction grating 165 has a light-transmitting portion in a slit form, a dot form, a mesh form, or the like with intervals which are less than or equal to the resolution limit of light used for the exposure, whereby the light transmittance can be controlled. The diffraction grating 165 can be in a slit form, a dot form, or a mesh form with regular intervals; or in a slit form, a dot form, or a mesh form with irregular intervals.

For the light-transmitting substrate 163, a substrate having a light-transmitting property, such as a quartz substrate, can be used. The light-blocking portion 164 and the diffraction grating 165 can be formed using a light-blocking material such as chromium or chromium oxide, which absorbs light.

When the gray-tone mask 59a is irradiated with light for exposure, a light transmittance 166 of the light-blocking portion 164 is 0% and that of a region where neither the light-blocking portion 164 nor the diffraction grating 165 is provided is 100%, as shown in FIG. 8B. The light transmittance of the diffraction grating 165 can be controlled in a range of from 10% to 70%. The light transmittance of the diffraction grating 165 can be controlled with an interval or a pitch of slits, dots, or meshes of the diffraction grating.

As shown in FIG. 8C, the half-tone mask 59b includes a light-transmitting substrate 163 provided with a semi-light-transmitting portion 167 and a light-blocking portion 168. MoSiN, MoSi, MoSiO, MoSiON, CrSi, or the like can be used for the semi-light-transmitting portion 167. The light-blocking portion 168 can be formed using a light-blocking material such as chromium or chromium oxide, which absorbs light.

When the half-tone mask 59b is irradiated with light for exposure, a light transmittance 169 of the light blocking portion 168 is 0% and that of a region where neither the light-blocking portion 168 nor the semi-light-transmitting portion 167 is provided is 100%, as shown in FIG. 8D. The light transmittance of the semi-light-transmitting portion 167 can be controlled in a range of from 10% to 70%. The light transmittance of the semi-light-transmitting portion 167 can be controlled with the material of the semi-light-transmitting portion 167.

After the light exposure using the multi-tone photomask is performed, development is carried out, whereby a resist mask 81 having regions with different thicknesses can be formed, as shown in FIG. 9B.

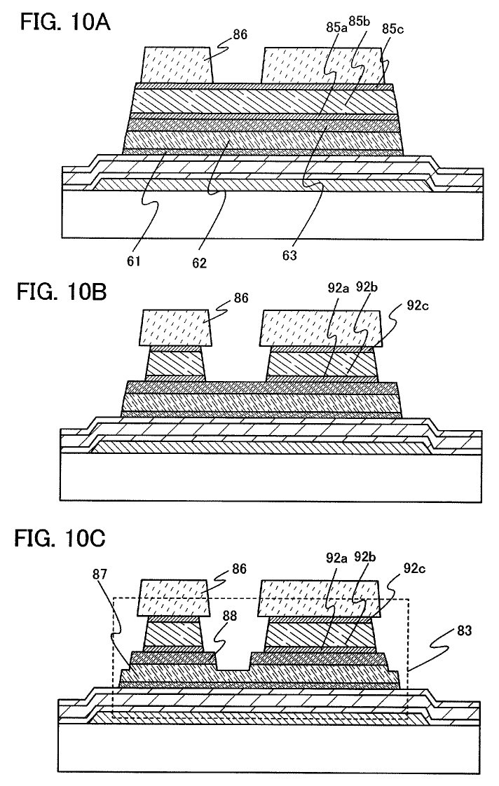

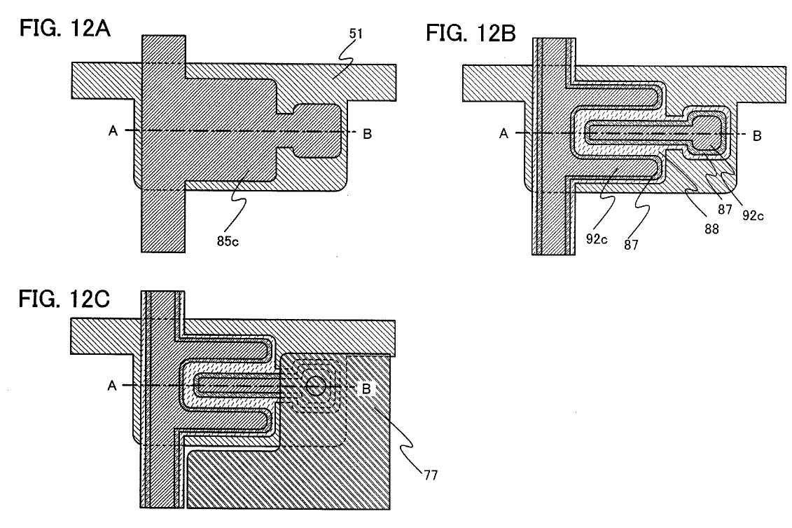

Next, with the resist mask 81, the microcrystalline semiconductor film 53, the buffer layer 54, the semiconductor film 55 to which the impurity element imparting one conductivity type is added, and the conductive films 65a to 65c are etched to be separated. As a result, a microcrystalline semiconductor film 61, a buffer layer 62, a semiconductor film 63 to which the impurity element imparting one conductivity type is added, and conductive films 85a to 85c can be formed, as shown in FIG. 10A. FIG. 10A is a cross-sectional view taken along a line A-B in FIG. 12A (although a resist mask 86 is not illustrated in FIGS. 12A to 12C).

Next, the resist mask 81 undergoes ashing. As a result, the area and the thickness of the resist mask is reduced. At this time, the resist mask in a region with a small thickness (a region overlapping with part of the gate electrode 51) is removed to form the separated resist mask 86, as shown in FIG. 10A.

Next, the conductive films 85a to 85c are etched to be separated using the resist mask 86. Here, the conductive films 85a to 85c are separated by dry etching. As a result, pairs of source and drain electrodes 92a to 92c can be formed as shown in FIG. 10B. When the conductive films 85a to 85c are wet-etched using the resist mask 86, the conductive films 85a to 85c are etched isotropically. Thus, source and drain electrodes 92a to 92c with smaller areas than that of the resist mask 86 can be formed.

Next, the semiconductor film 63 to which the impurity element imparting one conductivity type is added is etched using the resist mask 86 to form a pair of source and drain regions 88. In the etching process, part of the buffer layer 62 is also etched. The buffer layer which is etched partly is referred to as a buffer layer 87. In the buffer layer 87, a recessed portion is formed. The source and drain regions and the recessed portion of the buffer layer can be formed in the same process. Here, the buffer layer 87 is partly etched with the use of the resist mask 86 having a smaller area than that of the resist mask 81, so that an end portion of the buffer layer 87 is located at outer side than those of the source and drain regions 88. After that, the resist mask 86 is removed. End portions of the source and drain electrodes 92a to 92c are not aligned with those of the source and drain regions 88, and the end portions of the source and drain regions 88 are located at outer side than those of the source and drain electrodes 92a to 92c.

FIG. 10C is a cross-sectional view taken along a line A-B in FIG. 12B. As shown in FIG. 12B, the end portions of the source and drain regions 88 are located at outer side than those of the source and drain electrodes 92c. Further, the end portion of the buffer layer 87 is located at outer side than those of the source and drain electrodes 92c and those of the source and drain regions 88. Furthermore, one of the source and the drain electrodes surrounds the other of the source and drain electrodes (specifically, the former electrode is in a U-shape or a C-shape). Therefore, the area of a region where carriers travel can be increased; thus, the amount of current can be increased, and the area of the thin film transistor can be reduced. Further, unevenness at an end portion of the gate electrode has little influence on the films and layers thereover because the microcrystalline semiconductor film and the source and drain electrodes overlap with each other over the gate electrode, thereby curbing reduction in coverage and generation of leakage current. Either the source electrode or the drain electrode also functions as a source wiring or a drain wiring.

As shown in FIG. 10C, the end portions of the source and drain electrodes 92a to 92c are not aligned with those of the source and drain regions 88, whereby the distance between the end portions of the source and drain electrodes 92a to 92c can be long; thus, leakage current or short circuit between the source and drain electrodes can be prevented. Accordingly, a thin film transistor with high reliability and high withstand voltage can be manufactured.

Through the above process, a thin film transistor 83 can be formed. The thin film transistor can be formed with the use of the two photomasks.

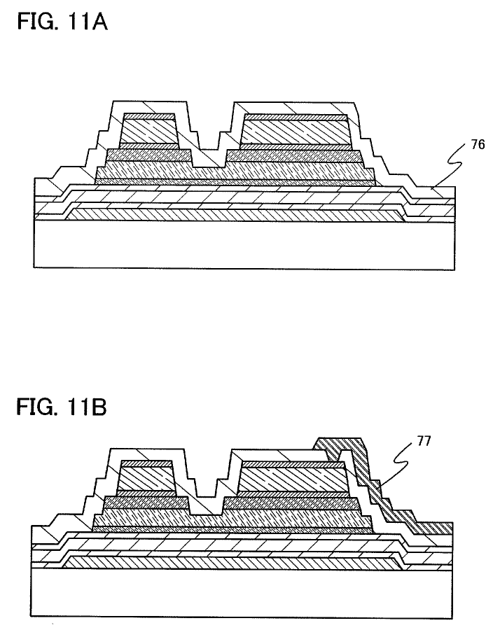

Next as shown in FIG. 11A, an insulating film 76 is formed over the source and drain electrodes 92a to 92c, the source and drain regions 88, the buffer layer 87, the microcrystalline semiconductor film 61, and the gate insulating film 52c. The insulating film 76 can be formed in a similar manner to the gate insulating films 52a to 52c.

Next, a contact hole is formed in the insulating film 76 by partly etching the insulating film 76 using a resist mask formed using a third photomask. Then, a pixel electrode 77 that is in contact with the source or drain electrode 92c in the contact hole is formed. In this example, an indium tin oxide film is formed as the pixel electrode 77 by a sputtering method, and then a resist is applied over the indium tin oxide film. Subsequently, the resist is exposed to light and developed using a fourth photomask, thereby forming a resist mask. Then, the indium tin oxide film is etched using the resist mask to form the pixel electrode 77. FIG. 11B is a cross-sectional view taken along a line A-B in FIG. 12C.

In the above manner, an element substrate which can be used for a display device can be formed using a multi-tone photomask to reduce the number of masks.

This embodiment mode can be combined with any one of Embodiment Modes 1 to 3 as appropriate.

### Embodiment Mode 6

Hereinafter, this embodiment mode describes a liquid crystal display device including the thin film transistor in the above Embodiment Modes as one mode of a display device.

First, a vertical alignment (VA) mode liquid crystal display device is described. The VA mode liquid crystal display device employs a method of controlling alignment of liquid crystal molecules of a liquid crystal panel. In the VA mode liquid crystal display device, liquid crystal molecules are aligned in a vertical direction with respect to a panel surface when a voltage is not applied. In this embodiment mode, in particular, a pixel is divided into some regions (subpixels), and molecules are aligned in different directions in their respective regions. This is referred to as multi-domain or multi-domain design. Hereinafter, a liquid crystal display device of multi-domain design is described.

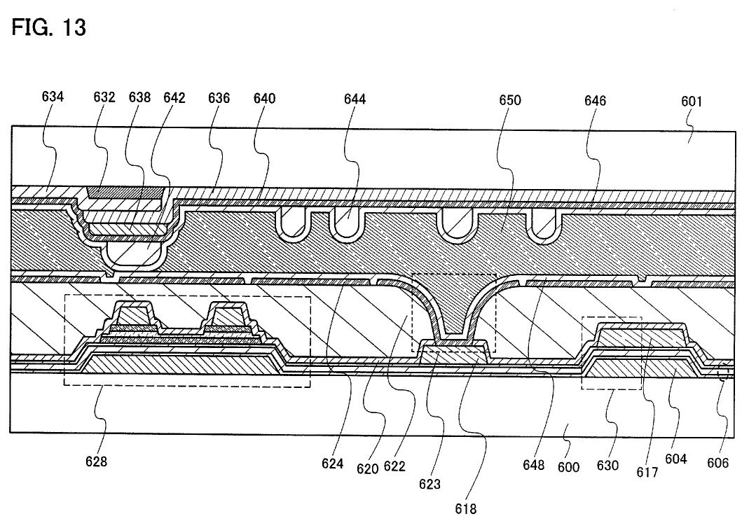

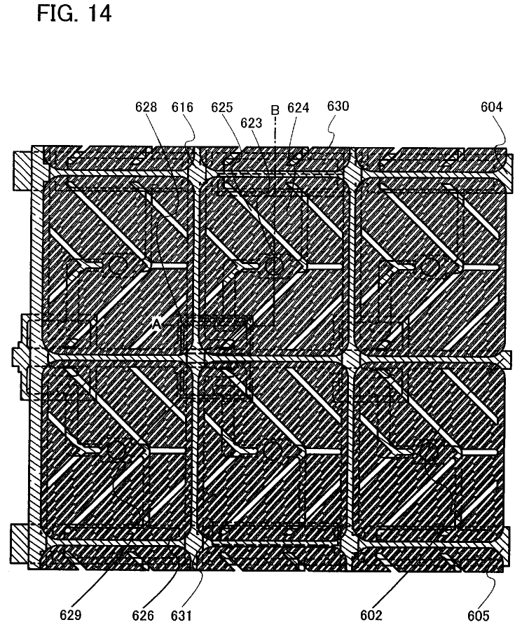

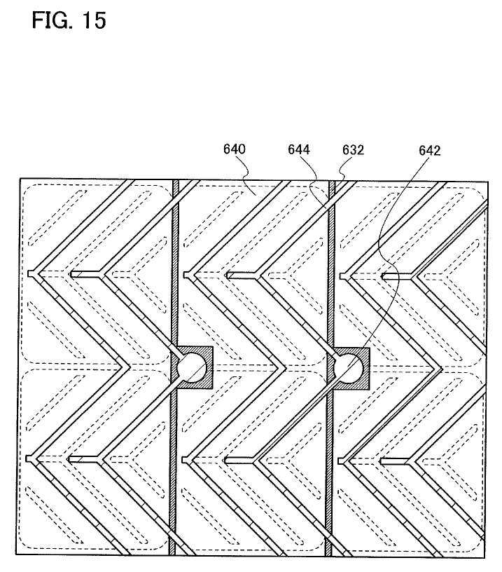

FIGS. 14 and 15 show a pixel electrode and a counter electrode, respectively. FIG. 14 is a plan view on a substrate side over which the pixel electrode is formed. FIG. 13 shows a cross-sectional structure taken along a line A-B in FIG. 14. FIG. 15 is a plan view on a substrate side over which the counter electrode is formed. Hereinafter, description is made with reference to these drawings.

In FIG. 13, a substrate 600 over which a TFT 628, a pixel electrode 624 connected to the TFT 628, and a holding capacitor portion 630 are formed and a counter substrate 601 for which a counter electrode 640 and the like are provided are superposed on each other, and liquid crystals are injected between the substrate 600 and the counter substrate 601.

A light blocking film 632, a first coloring film 634, a second coloring film 636, a third coloring film 638, and the counter electrode 640 are formed in a position where a spacer 642 is provided for the counter substrate 601. This structure makes the height of projections 644 for controlling alignment of liquid crystals different from that of the spacer 642. An alignment film 648 is formed over the pixel electrode 624, and the counter electrode 640 is similarly provided with an alignment film 646. A liquid crystal layer 650 is formed between the alignment films 646 and 648.

Although a columnar spacer is used as the spacer 642 here, bead spacers may be dispersed instead. Further, the spacer 642 may be formed over the pixel electrode 624 formed over the substrate 600.

The TFT 628, the pixel electrode 624 connected to the TFT 628, and the holding capacitor portion 630 are formed over the substrate 600. The pixel electrode 624 is connected to a wiring 618 in a contact hole 623 that passes through an insulating film 620 covering the TFT 628, the wiring 618, and the holding capacitor portion 630, and through a third insulating film 622 covering the insulating film 620. The thin film transistor shown in the above Embodiment Modes can be used as appropriate for the TFT 628. Further, the holding capacitor portion 630 includes a first capacitor wiring 604 that is formed at the same time as a gate wiring 602 of the TFT 628; a gate insulating film 606; and a second capacitor wiring 617 that is formed at the same time as a wiring 616 and the wiring 618.

The pixel electrode 624, the liquid crystal layer 650, and the counter electrode 640 overlap with each other, so that a liquid crystal element is formed.

FIG. 14 shows a structure over the substrate 600. The pixel electrode 624 is formed using a material shown in Embodiment Mode 1. Slits 625 are formed in the pixel electrode 624. The slits 625 are formed to control alignment of the liquid crystals.

A TFT 629, a pixel electrode 626 connected to the TFT 629, and a holding capacitor portion 631, which are shown in FIG. 14, can be formed in a similar manner to the TFT 628, the pixel electrode 624, and the holding capacitor portion 630, respectively. Both the TFTs 628 and 629 are connected to the wiring 616. A pixel of this liquid crystal panel includes the pixel electrodes 624 and 626. The pixel electrodes 624 and 626 are subpixels.

FIG. 15 shows a structure on the counter substrate side. The counter electrode 640 is formed over the light blocking film 632. It is preferable to use a similar material to the pixel electrode 624 to form the counter electrode 640. The projections 644 that control alignment of liquid crystals are formed over the counter electrode 640. Moreover, the spacer 642 is formed in accordance with the position of the light blocking film 632.

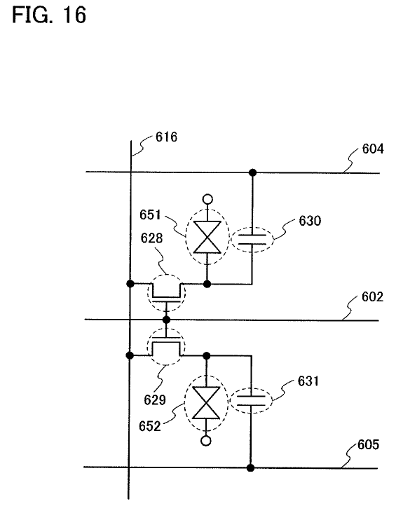

FIG. 16 shows an equivalent circuit of this pixel structure. Both the TFTs 628 and 629 are connected to the gate wiring 602 and the wiring 616. In this case, by making the potential of the first capacitor wiring 604 different from that of a capacitor wiring 605, operation of a liquid crystal element 651 can be different from that of a liquid crystal element 652. Specifically, potentials of the first capacitor wiring 604 and the capacitor wiring 605 are controlled individually, thereby precisely controlling alignment of liquid crystals to increase a viewing angle.

When a voltage is applied to the pixel electrode 624 provided with the slits 625, a distorted electric field (an oblique electric field) is generated near the slits 625. The slits 625 and the projections 644 on the counter substrate 601 side are disposed in an alternate form, thereby effectively generating the oblique electric field to control alignment of the liquid crystals, and thus the direction in which liquid crystals are aligned is different depending on the location. Specifically, the viewing angle of a liquid crystal panel is increased by employing multi-domain.

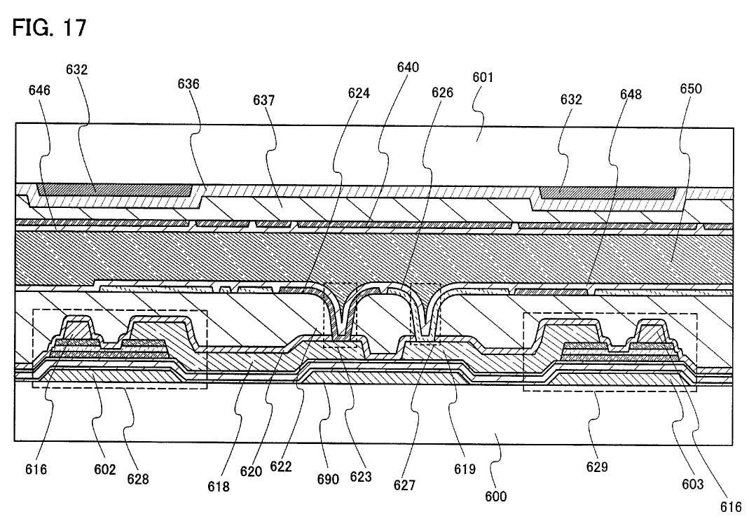

Next, a different VA mode liquid crystal display device from the above is described with reference to FIGS. 17 to 20.

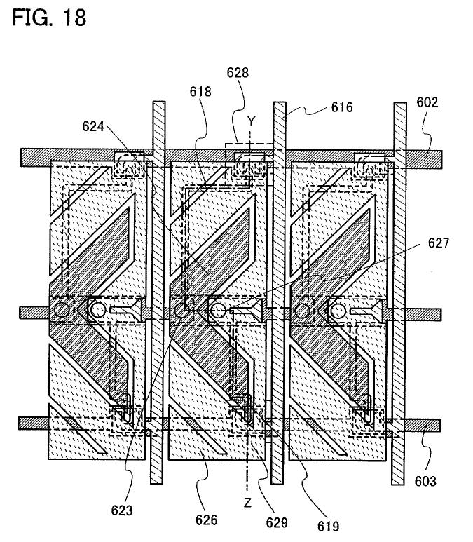

FIGS. 17 and 18 show a pixel structure of a VA mode liquid crystal panel. FIG. 18 is a plan view over a substrate 600. FIG. 17 shows a cross-sectional structure taken along a line Y-Z in FIG. 18. The following description is made with reference to both the drawings.

In this pixel structure, one pixel has a plurality of pixel electrodes, and a TFT is connected to each pixel electrode. Each TFT is driven with a different gate signal from each other. Specifically, in the pixel of multi-domain design, a signal applied to each pixel electrode is controlled independently.

A pixel electrode 624 is connected to a TFT 628 through a wiring 618 in a contact hole 623. In addition, a pixel electrode 626 is connected to a TFT 629 through a wiring 619 in a contact hole 627. A gate wiring 602 of the TFT 628 is separated from a gate wiring 603 of the TFT 629 so that different gate signals can be supplied thereto. On the other hand, a wiring 616 serving as a data line is shared by the TFTs 628 and 629. The thin film transistor shown in Embodiment Mode 1 can be used as appropriate for the TFTs 628 and 629.

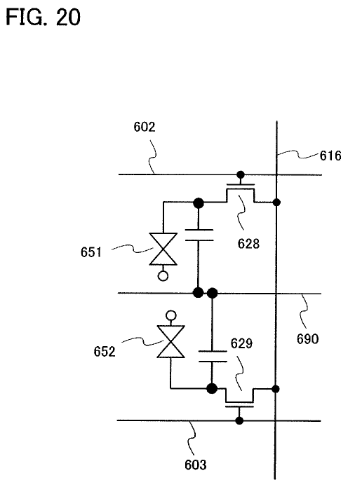

The shape of the pixel electrode 624 is different from that of the pixel electrode 626, and the pixel electrodes 624 and 626 are separated by slits 625. The pixel electrode 626 surrounds the pixel electrode 624, which has a V-shape. The TFTs 628 and 629 make the timing of applying a voltage to the pixel electrodes 624 and 626 different from each other, thereby controlling the alignment of liquid crystals. FIG. 20 shows an equivalent circuit of this pixel structure. The TFT 628 is connected to the gate wiring 602, and the TFT 629 is connected to the gate wiring 603. When different gate signals are supplied to the gate wirings 602 and 603, operation timing of the TFTs 628 and 629 can be different. Further, the TFT 628 is connected to a first liquid crystal element 651, and the TFT 629 is connected to a second liquid crystal element 652. Furthermore, pixel electrodes of the first liquid crystal element 651 and the second liquid crystal element 652 are connected to each other through a capacitor wiring 690 and capacitors.

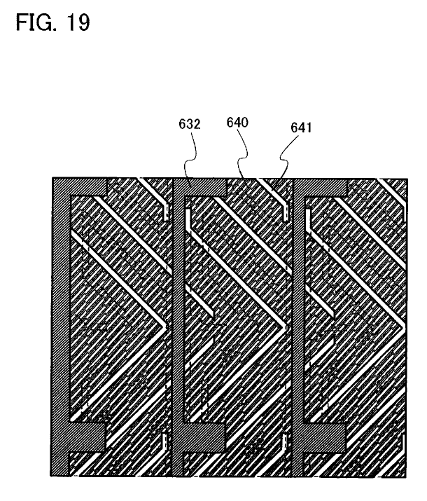

A counter substrate 601 is provided with a light blocking film 632, a second coloring film 636, and a counter electrode 640. In addition, a planarizing film 637 is formed between the second coloring film 636 and the counter electrode 640, thereby preventing alignment disorder of liquid crystals. FIG. 19 shows a structure of the counter substrate side. The counter electrode 640 is shared by plural pixels, and slits 641 are formed in the counter electrode 640. The slits 641 and the slits 625 on the pixel electrodes 624 and 626 side are disposed in an alternate form, thereby effectively generating an oblique electric field to control the alignment of the liquid crystals. Accordingly, the direction in which the liquid crystals are aligned can be different depending on the location, and thus a viewing angle of the liquid crystal display panel is increased.

The pixel electrode 624, a liquid crystal layer 650, and the counter electrode 640 overlap with each other, so that a first liquid crystal element is formed. Further, the pixel electrode 626, the liquid crystal layer 650, and the counter electrode 640 overlap with each other, so that a second liquid crystal element is formed. Furthermore, the multi-domain structure is made in which the first liquid crystal element and the second liquid crystal element are provided for one pixel.

Next, a liquid crystal display device in a horizontal electric field mode is presented. In a horizontal field effect mode, an electric field is applied in a horizontal direction with respect to liquid crystal molecules in a cell, whereby liquid crystals are driven to express gray scales. In accordance with this method, a viewing angle can be expanded to approximately 180°. Hereinafter, a liquid crystal display device in the horizontal electric field mode is described.

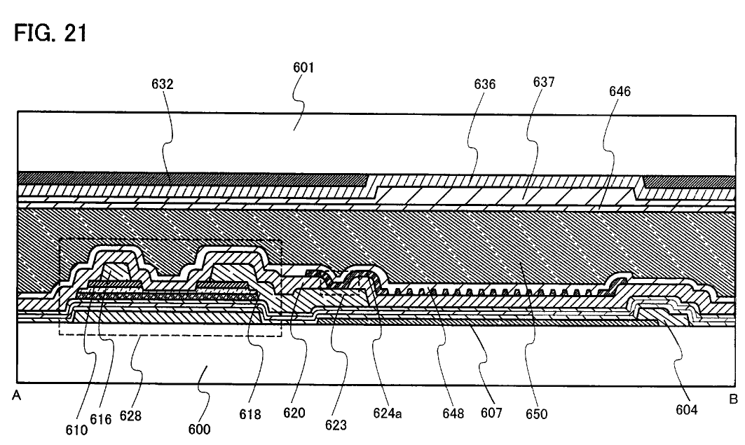

In FIG. 21, a counter substrate 601 is superposed on a substrate 600 over which a TFT 628 and a pixel electrode 624 connected to the TFT 628 are formed, and liquid crystals are injected therebetween. The counter substrate 601 is provided with a light blocking film 632, a second coloring film 636, a planarizing film 637, and the like. The pixel electrode is provided for the substrate 600, and not for the counter substrate 601. A liquid crystal layer 650 is formed between the substrate 600 and the counter substrate 601.

A first pixel electrode 607, a capacitor wiring 604 connected to the first pixel electrode 607, and the TFT 628 shown in Embodiment Mode 1 are formed over the substrate 600. The first pixel electrode 607 can be formed using a similar material to the pixel electrode 77 shown in Embodiment Mode 1. The first pixel electrode 607 is formed to be compartmentalized almost in a pixel form. A gate insulating film 606 is formed over the first pixel electrode 607 and the capacitor wiring 604.

Wirings 616 and 618 of the TFT 628 are formed over the gate insulating film 606. The wiring 616 is a data line through which a video signal travels, extends in one direction in a liquid crystal display panel, is connected to a source or drain region 610 of the TFT 628, and functions as one of source and drain electrodes. The wiring 618 functions as the other of the source and drain electrodes and is connected to the second pixel electrode 624a.

A second insulating film 620 is formed over the wirings 616 and 618. Further, the second pixel electrode 624a that is connected to the wiring 618 in a contact hole formed in the insulating film 620 is formed over the insulating film 620. The pixel electrode 624a is formed using a similar material to the pixel electrode 77 shown in Embodiment Mode 1.

In the above manner, the TFT 628 and the second pixel electrode 624a connected to the TFT 628 are formed over the substrate 600. A holding capacitor is formed between the first pixel electrode 607 and the second pixel electrode 624a.

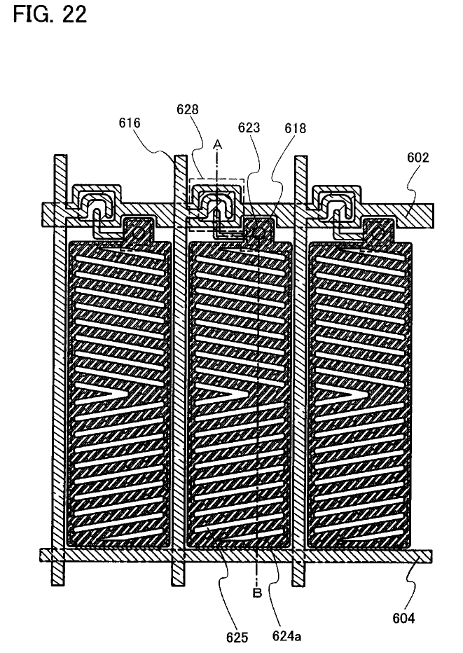

FIG. 22 is a plan view showing a structure of the pixel electrode. The pixel electrode 624a is provided with slits 625. The slits 625 are provided to control the alignment of the liquid crystals. In this case, an electric field is generated between the first pixel electrode 607 and the second pixel electrode 624a. Although the gate insulating film 606 is formed between the first pixel electrode 607 and the second pixel electrode 624a, the gate insulating film 606 has a thickness of from 50 nm to 200 nm, which is thin enough as compared with the liquid crystal layer with a thickness of from 2 μm to 10 μm. Therefore, the electric field is generated in a direction which is parallel to the substrate 600 (a horizontal direction). The alignment of the liquid crystals is controlled with this electric field. Liquid crystal molecules are horizontally rotated with the use of the electric field in the direction parallel or substantially parallel to the substrate. In this case, since the liquid crystal molecules are horizontally aligned in any state, contrast or the like is less influenced by the viewing angle; thus, the viewing angle is increased. In addition, the aperture ratio can be improved since both the first pixel electrode 607 and the second pixel electrode 624a are light-transmitting electrodes.

Next, a different example of a liquid crystal display device in a horizontal electric field mode is presented.

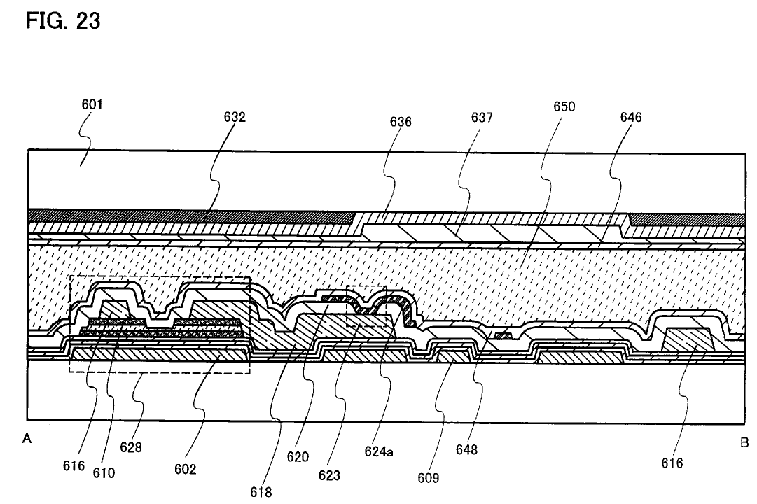

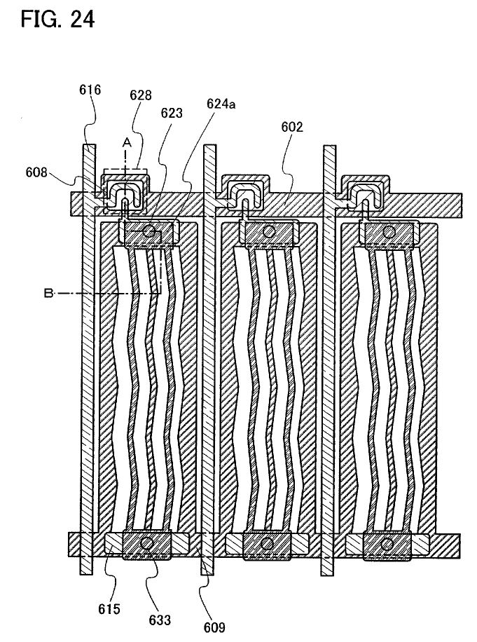

FIGS. 23 and 24 show a pixel structure of a liquid crystal display device in an IPS mode. FIG. 24 is a plan view, and FIG. 23 shows a cross-sectional structure taken along a line A-B in FIG. 24. Hereinafter, description is made with reference to both the drawings.

In FIG. 23, a counter substrate 601 is superposed on a substrate 600 over which a TFT 628 and a pixel electrode 624a connected to the TFT 628 are formed, and liquid crystals are injected between the substrate 600 and the counter substrate 601. The counter substrate 601 is provided with a light blocking film 632, a second coloring film 636, a planarizing film 637, and the like. The pixel electrode is provided for the substrate 600, and not for the counter substrate 601. A liquid crystal layer 650 is formed between the substrate 600 and the counter substrate 601.

A common potential line 609 and the TFT 628 shown in Embodiment Mode 1 are formed over the substrate 600. The common potential line 609 can be formed at the same time as forming a gate wiring 602 of the TFT 628. The second pixel electrode 624a is compartmentalized almost in a pixel form.

Wirings 616 and 618 of the TFT 628 are formed over a gate insulating film 606. The wiring 616 is a data line through which a video signal travels, extends in one direction in a liquid crystal display panel, is connected to a source or drain region 610, and functions as one of source and drain electrodes. The wiring 618 functions as the other of the source and drain electrodes and is connected to the second pixel electrode 624a.

A second insulating film 620 is formed over the wirings 616 and 618. Further, the second pixel electrode 624a that is connected to the wiring 618 in a contact hole 623 formed in the insulating film 620 is formed over the insulating film 620. The pixel electrode 624a is formed using a similar material to the pixel electrode 77 shown in Embodiment Mode 1. As shown in FIG. 24, the pixel electrode 624a is formed such that the pixel electrode 624a and a comb-like electrode that is formed at the same time as the common potential line 609 can generate a horizontal electric field. Further, a comb-like portion of the pixel electrode 624a and the comb-like electrode that is formed at the same time as the common potential line 609 and corresponds to the comb-like portion of the pixel electrode 624a are formed so as to be placed in an alternate form.

When an electric field is generated between the potential applied to the pixel electrode 624a and that to the common potential line 609, the alignment of liquid crystals is controlled with this electric field. Liquid crystal molecules are horizontally rotated with the use of the electric field in the direction parallel or substantially parallel to the substrate. In this case, since the liquid crystal molecules are horizontally aligned in any state, the contrast or the like is less influenced by the viewing angle; thus, the viewing angle is increased.

In the above manner, the TFT 628 and the pixel electrode 624a connected to the TFT 628 are formed over the substrate 600. A holding capacitor is formed by providing the gate insulating film 606 between the common potential line 609 and a capacitor electrode 615. The capacitor electrode 615 is connected to the pixel electrode 624a through a contact hole 633.

Next, a liquid crystal display device in a TN mode is shown.

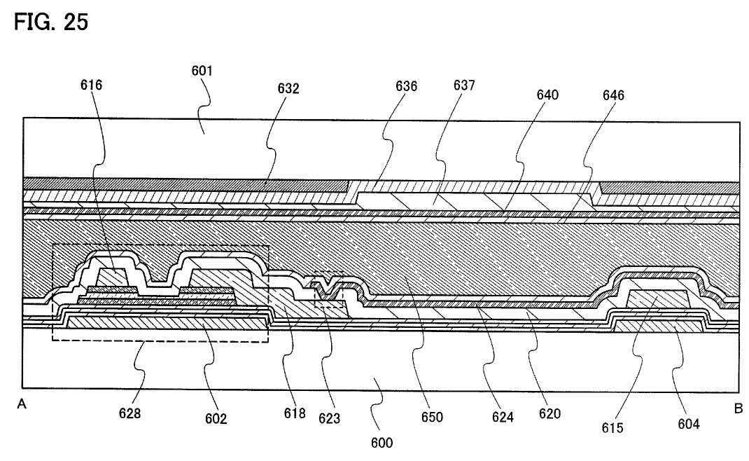

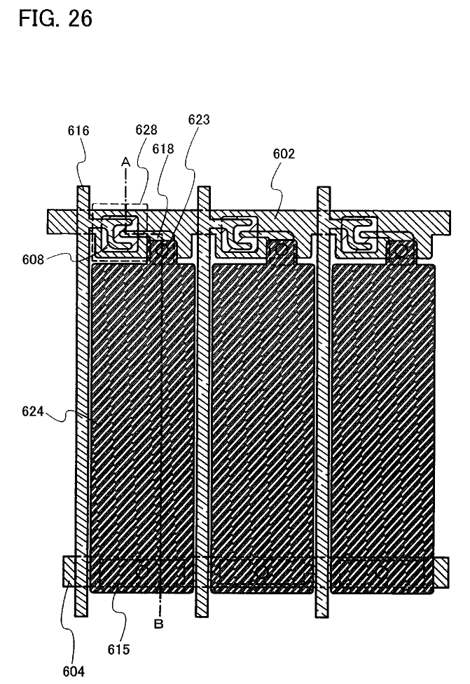

FIGS. 25 and 26 show a pixel structure of a liquid crystal display device in a TN mode. FIG. 26 is a plan view, and FIG. 25 shows a cross-sectional structure taken along a line A-B in FIG. 26. Hereinafter, description is made with reference to both the drawings.

A pixel electrode 624 is connected to a TFT 628 through a wiring 618 in a contact hole 623. A wiring 616 functioning as a data line is also connected to the TFT 628. Any TFT shown in Embodiment Mode 1 can be used for the TFT 628.

The pixel electrode 624 is formed using the pixel electrode 77 shown in Embodiment Mode 1.

A counter substrate 601 is provided with a light blocking film 632, a second coloring film 636, and a counter electrode 640. In addition, a planarizing film 637 is formed between the second coloring film 636 and the counter electrode 640 to prevent alignment disorder of liquid crystals. A liquid crystal layer 650 is formed between the pixel electrode 624 and the counter electrode 640.

The pixel electrode 624, the liquid crystal layer 650, and the counter electrode 640 overlap with each other, so that a liquid crystal element is formed.

The counter electrode 640 can be formed using a similar material to the pixel electrode 77 as appropriate.

Further, a polarizing plate is attached to a surface of the substrate 600 which is opposite to the surface provided with the thin film transistor, and another polarizing plate is attached to a surface of the counter substrate 601 which is opposite to the surface provided with the counter electrode 640.

Through the above process, a liquid crystal display device can be manufactured. The liquid crystal display device in this embodiment mode has high contrast and high visibility because a thin film transistor with little off current, excellent electric characteristics, and high reliability is used in the liquid crystal display device.

### Embodiment Mode 7

This embodiment mode describes a light-emitting device, which is one mode of a display device, with reference to FIGS. 9A and 9B, FIGS. 10A to 10C, FIGS. 11A and 11B, FIGS. 27A and 27B, and FIGS. 28A to 28C. Here, a light-emitting element utilizing electroluminescence is presented as a light-emitting device. Light-emitting elements utilizing electroluminescence are classified into two types according to whether the light-emitting material is an organic compound or an inorganic compound. In general, the former is referred to as an organic EL element and the latter is referred to as an inorganic EL element.

In an organic EL element, voltage is applied to the light-emitting element, so that electrons are injected from an electrode into a layer including a light-emitting organic compound, and holes are injected from the other electrode into the layer including the light-emitting organic compound, and there flows electric current. These carriers (electrons and holes) are recombined, so that the light-emitting organic compound is placed in an excited state. The light-emitting organic compound emits light in returning to a ground state from the excited state. Because of such mechanism, such a light-emitting element is called a light-emitting element of a current excitation type.

Inorganic EL elements are classified into dispersive inorganic EL elements and thin film inorganic EL elements. A dispersive inorganic EL element includes a light-emitting layer in which particles of a light-emitting material are dispersed in a binder, and light emission mechanism thereof is donor-acceptor recombination light emission, in which a donor level and an acceptor level are utilized. In a thin film inorganic EL element, a light-emitting layer is sandwiched between dielectric layers, and the dielectric layers are sandwiched between electrodes. Light emission mechanism of the thin film inorganic EL element is local light emission, in which inner-shell electron transition of a metal ion is utilized. Here, an organic EL element is described as a light-emitting element. Further, description is made using the thin film transistor in Embodiment Mode 1 as a thin film transistor which controls driving of a light-emitting element. In a light-emitting device in which the thin film transistor obtained according to Embodiment Mode 1 is used, variation in threshold voltage of the thin film transistor can be suppressed and thus reliability can be improved. In particular, a thin film transistor which is used in a light-emitting device is driven by direct current; thus, the thin film transistor in Embodiment Mode 1 that has a gate insulating film with a three-layer structure including a silicon nitride film as a first layer, a silicon oxynitride film as a second layer, and a silicon nitride film as a third layer can suppress a drift of the threshold voltage mainly owing to the silicon oxynitride film of the second layer.

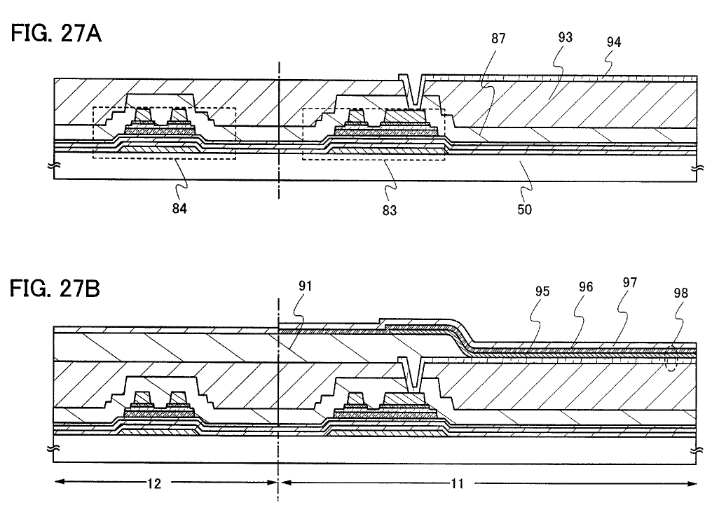

Through the steps shown in FIGS. 9A and 9B, FIGS. 10A to 10C, and FIGS. 11A and 11B, a thin film transistor 83 is formed over a substrate 50, and an insulating film 87 serving as a protective film is formed over the thin film transistor 83, as shown in FIGS. 27A and 27B. Further, a thin film transistor 84 is formed in a driver circuit 12. The thin film transistor 84 can be formed in the same manufacturing process of the thin film transistor 83 in a pixel portion 11. Subsequently, a planarizing film 93 is formed over the insulating film 87, and a pixel electrode 94 that is connected to a source or drain electrode of the thin film transistor 83 is formed over the planarizing film 93.

It is preferable to form the planarizing film 93 using an organic resin such as acrylic, polyimide, or polyamide, or siloxane.

In FIG. 27A, since the thin film transistor in the pixel portion 11 is an n-channel TFT, it is preferable to use a cathode as the pixel electrode 94; if the thin film transistor in the pixel portion is a p-channel TFT, it is preferable to use an anode as the pixel electrode 94. Specifically, for the cathode, a known material with a low work function, such as calcium, aluminum, magnesium-silver alloy, or lithium-aluminum alloy, can be used.

Subsequently, as shown in FIG. 27B, a partition wall 91 is formed over the planarizing film 93 and an end portion of the pixel electrode 94. The partition wall 91 has an opening portion, and the pixel electrode 94 is exposed in the opening portion. The partition wall 91 is formed using an organic resin film, an inorganic insulating film, or an organic polysiloxane film. In particular, it is preferable that the partition wall 91 be formed of a photosensitive material; the opening portion be formed over the pixel electrode; and a side wall of the opening portion form an inclined surface with a continuous curvature.

Then, a light-emitting layer 95 is formed so as to be in contact with the pixel electrode 94 in the opening portion of the partition wall 91. The light-emitting layer 95 may be formed using a single layer or by stacking a plurality of layers.

Subsequently, a common electrode 96 is formed using an anode material so as to cover the light-emitting layer 95. The common electrode 96 can be formed using a light-transmitting conductive film which is formed using a light-transmitting conductive material and is given as the pixel electrode 77 in Embodiment Mode 1. The common electrode 96 may also be formed using a titanium nitride film or a titanium film instead of the above light-transmitting conductive film. In FIG. 27B, the common electrode 96 is formed using indium tin oxide. In the opening portion of the partition wall 91, the pixel electrode 94, the light-emitting layer 95, and the common electrode 96 overlap with each other, so that a light-emitting element 98 is formed. After that, a protective film 97 is preferably formed over the common electrode 96 and the partition wall 91 so that oxygen, hydrogen, moisture, carbon dioxide, and the like do not enter the light-emitting element 98. As the protective film 97, a silicon nitride film, a silicon nitride oxide film, a DLC film, or the like can be formed.

Further, in a practical case, it is preferable that a display device completed to the state illustrated in FIG. 27B be packaged (sealed) with a protective film (e.g., a laminated film or an ultraviolet curable resin film) or a cover material with high air-tightness and little degasification so that the display device is not exposed to outside air.

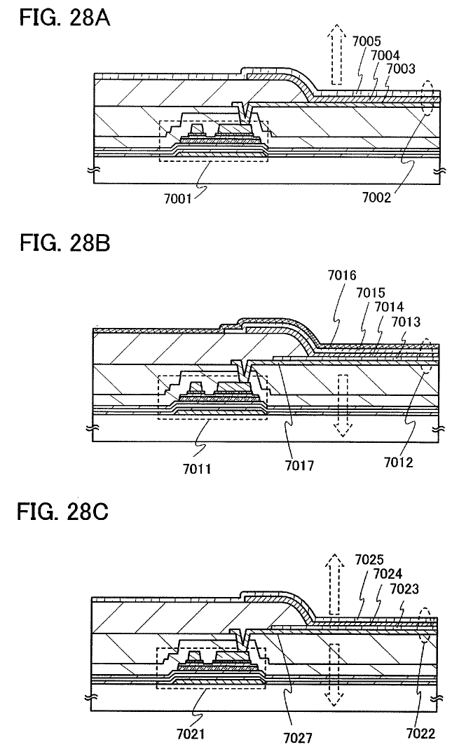

Next, structures of a light-emitting element are described with reference to FIGS. 28A to 28C. Here, a cross-sectional structure of a pixel is described by taking an n-channel driving TFT as an example.

In order to extract light emission of the light-emitting element, at least one of an anode and a cathode may be transparent. A thin film transistor and a light-emitting element are formed over a substrate. A light-emitting element can have a top emission structure, in which light is emitted through the surface opposite to the substrate; a bottom emission structure, in which light is emitted through the surface on the substrate side; or a dual emission structure, in which light is emitted through the surface opposite to the substrate and the surface on the substrate side. The pixel structure of the present invention can be applied to a light-emitting element having any of these emission structures.

A light-emitting element having the top emission structure is described with reference to FIG. 28A.

FIG. 28A is a cross-sectional view of a pixel in a case where a driving TFT 7001 is an n-channel TFT, and light generated in a light-emitting element 7002 is emitted to pass through an anode 7005. In FIG. 28A, a cathode 7003 of the light-emitting element 7002 and the driving TFT 7001 are electrically connected to each other. An EL layer 7004 and the anode 7005 are stacked in order over the cathode 7003. As the cathode 7003, a known conductive film can be used as long as it has a low work function and reflects light. For example, calcium, aluminum, calcium fluoride, magnesium-silver alloy, lithium-aluminum alloy, or the like is preferably used. The EL layer 7004 may be formed using a single layer or by stacking a plurality of layers. If the EL layer 7004 is formed using a plurality of layers, the EL layer 7004 is formed by stacking an electron-injecting layer, an electron-transporting layer, a light-emitting layer, a hole-transporting layer, and a hole-injecting layer in this order over the cathode 7003. It is not necessary to form all of these layers. The anode 7005 is formed using a light-transmitting conductive film such as a film of indium oxide including tungsten oxide, indium zinc oxide including tungsten oxide, indium oxide including titanium oxide, indium tin oxide including titanium oxide, indium tin oxide, indium zinc oxide, or indium tin oxide to which silicon oxide is added.

The light-emitting element 7002 corresponds to a region where the cathode 7003 and the anode 7005 sandwich the EL layer 7004. In the pixel shown in FIG. 28A, light generated in the light-emitting element 7002 is emitted to pass through the anode 7005 as shown with an outline arrow.

Next, a light-emitting element having the bottom emission structure is described with reference to FIG. 28B. FIG. 28B is a cross-sectional view of a pixel in a case where a driving TFT 7011 is an n-channel TFT; and light generated in a light-emitting element 7012 is emitted to pass through a cathode 7013. In FIG. 28B, the cathode 7013 of the light-emitting element 7012 is formed over a light-transmitting conductive film 7017 that is electrically connected to the driving TFT 7011, and an EL layer 7014 and an anode 7015 are stacked in order over the cathode 7013. When the anode 7015 has a light-transmitting property, a blocking film 7016 for reflecting or blocking light may be formed so as to cover the anode. As the cathode 7013, a known conductive film can be used as in the case of FIG. 28A as long as it has a low work function; note that the cathode 7013 has a thickness that allows light to pass (preferably, about 5 nm to 30 nm). For example, an Al film having a thickness of 20 nm can be used as the cathode 7013. The EL layer 7014 may be formed using a single layer or by stacking a plurality of layers as in the case of FIG. 28A. The anode 7015 is not required to transmit light, but can be formed using a High-transmitting conductive material as in the case of FIG. 28A. For the blocking film 7016, a metal or the like that reflects light can be used; however, it is not limited to a metal film. For example, a resin or the like to which black pigments are added can be used.

The light-emitting element 7012 corresponds to a region where the cathode 7013 and the anode 7015 sandwich the EL layer 7014. In the pixel shown in FIG. 28B, light generated in the light-emitting element 7012 is emitted to pass through the cathode 7013 as shown with an outline arrow.

Next, a light-emitting element having the dual emission structure is described with reference to FIG. 28C. In FIG. 28C, a cathode 7023 of a light-emitting element 7022 is formed over a light-transmitting conductive film 7027 that is electrically connected to a driving TFT 7021, and an EL layer 7024 and an anode 7025 are stacked in order over the cathode 7023. As the cathode 7023, a known conductive film can be used as long as it has a low work function as in the case of FIG. 28A; note that the cathode 7023 has a thickness that allows light to pass. For example, an Al film having a thickness of 20 nm can be used as the cathode 7023. The EL layer 7024 may be formed using a single layer or by stacking a plurality of layers as in the case of FIG. 28A. The anode 7025 can be formed using a light-transmitting conductive material as in the case of FIG. 28A.

The light-emitting element 7022 corresponds to a region where the cathode 7023 and the anode 7025 sandwich the EL layer 7024. In the pixel shown in FIG. 28C, light generated in the light-emitting element 7022 is emitted to pass through both the anode 7025 and the cathode 7023 as shown with outline arrows.

Although an organic EL element is described as a light-emitting element, it is also possible to provide an inorganic EL element as a light-emitting element.

This embodiment mode describes an example in which a thin film transistor for controlling the drive of a light-emitting element (driving TFT) is electrically connected to the light-emitting element. However, a current control TFT may be formed between the driving TFT and the light-emitting element to be connected to them.

A light-emitting device described in this embodiment mode is not limited to the structures illustrated in FIGS. 28A to 28C, and can be modified in various ways based on the spirit of techniques according to the present invention.

Through the above process, a light-emitting device can be manufactured. The light-emitting device in this embodiment mode has high contrast and high visibility because a thin film transistor with little off current, excellent electric characteristics, and high reliability is used in the light-emitting device.

### Embodiment Mode 8

This embodiment mode describes a structure of a display panel, which is one mode of a display device of the present invention.

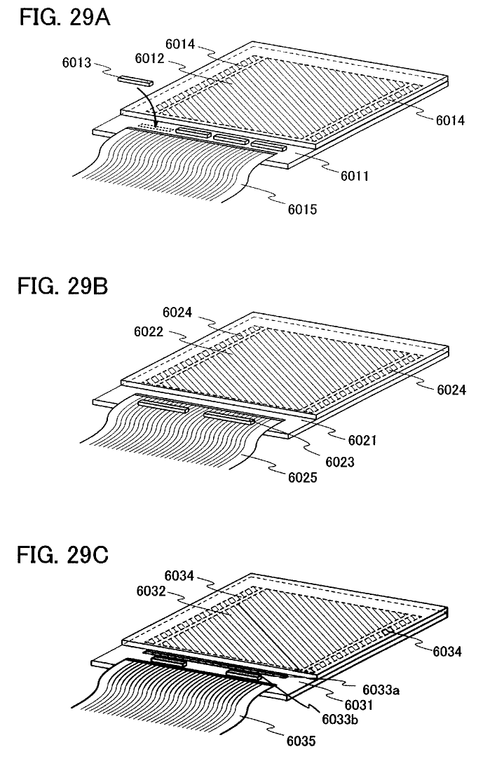

FIG. 29A shows a mode of a display panel in which a pixel portion 6012 formed over a substrate 6011 is connected to a signal line driver circuit 6013 that is formed separately. The pixel portion 6012 and a scanning line driver circuit 6014 are formed using thin film transistors in which microcrystalline semiconductor films are used for channel formation regions. By forming the signal line driver circuit with a thin film transistor by which higher mobility can be obtained compared to the thin film transistor in which the microcrystalline semiconductor film is used for the channel formation region, operation of the signal line driver circuit, which demands a higher driving frequency than the scanning line driver circuit, can be stabilized. The signal line driver circuit 6013 may be formed using a thin film transistor including a single-crystalline semiconductor, a thin film transistor including a polycrystalline semiconductor, or a thin film transistor including an SOI. The pixel portion 6012, the signal line driver circuit 6013, and the scanning line driver circuit 6014 are each supplied with potential of a power source, a variety of signals, and the like through an FPC 6015.

Both the signal driver circuit and the scanning line driver circuit may be formed over the same substrate as that of the pixel portion.

Further, if the driver circuit is formed separately, a substrate provided with the driver circuit is not always required to be attached to a substrate provided with the pixel portion, and may be attached to, for example, the FPC. FIG. 29B shows a mode of a display device panel in which a signal line driver circuit 6023 is formed separately and is connected to a pixel portion 6022 and a scanning line driver circuit 6024 that are formed over a substrate 6021. The pixel portion 6022 and the scanning line driver circuit 6024 are formed using thin film transistors in which microcrystalline semiconductor films are used for channel formation regions. The signal line driver circuit 6023 is connected to the pixel portion 6022 through an FPC 6025. The pixel portion 6022, the signal line driver circuit 6023, and the scanning line driver circuit 6024 are each supplied with potential of a power source, a variety of signals, and the like through the FPC 6025.

Furthermore, only a part of the signal line driver circuit or only a part of the scanning line driver circuit may be formed over the same substrate as that of the pixel portion, using a thin film transistor in which a microcrystalline semiconductor film is used for a channel formation region, and the rest may be formed separately and electrically connected to the pixel portion. FIG. 29C shows a mode of a display device panel in which an analog switch 6033a included in the signal line driver circuit is formed over a substrate 6031, over which a pixel portion 6032 and a scanning line driver circuit 6034 are formed, and a shift register 6033b included in the signal line driver circuit is formed separately over a different substrate and then attached to the substrate 6031. The pixel portion 6032 and the scanning line driver circuit 6034 are formed using thin film transistors in which microcrystalline semiconductor films are used for channel formation regions. The shift register 6033b included in the signal line driver circuit is connected to the pixel portion 6032 through an FPC 6035. The pixel portion 6032, the signal line driver circuit, and the scanning line driver circuit 6034 are each supplied with potential of a power source, a variety of signals, and the like through the FPC 6035.

As shown in FIGS. 29A to 29C, in the display device of the present invention, an entire driver circuit or a part thereof can be formed over the same substrate as that of a pixel portion, using a thin film transistor in which a microcrystalline semiconductor film is used for a channel formation region.

Note that there are no particular limitations on a connection method of a substrate formed separately, and a known method such as a COG method, a wire bonding method, or a TAB method can be used. Further, a connection position is not limited to the position illustrated in FIGS. 29A to 29C as long as electrical connection is possible. Further, a controller, a CPU, a memory, or the like may be formed separately and connected.

The signal line driver circuit used in the present invention is not limited to a mode having only a shift register and an analog switch. In addition to the shift register and the analog switch, another circuit such as a buffer, a level shifter, or a source follower may be included. Further, the shift register and the analog switch are not always required to be provided, and for example, a different circuit such as a decoder circuit by which selection of signal lines is possible may be used instead of the shift register, or a latch or the like may be used instead of the analog switch.

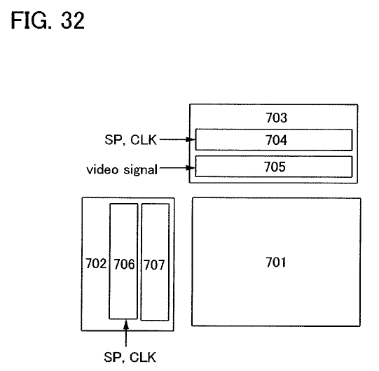

FIG. 32 is a block diagram of a display device of the present invention. The display device shown in FIG. 32 includes a pixel portion 701 including a plurality of pixels that is each provided with a display element, a scanning line driver circuit 702 that selects each pixel, and a signal line driver circuit 703 that controls a video signal input to a selected pixel.

In FIG. 32, the signal line driver circuit 703 includes a shift register 704 and an analog switch 705. A clock signal (CLK) and a start pulse signal (SP) are input to the shift register 704. When the clock signal (CLK) and the start pulse signal (SP) are input, a timing signal is generated in the shift register 704, and is input to the analog switch 705.

Further, a video signal is input to the analog switch 705. The analog switch 705 samples the video signal according to the input timing signal, and distributes the video signal to signal lines of latter stages.

Next, a configuration of the scanning line driver circuit 702 is described. The scanning line driver circuit 702 includes a shift register 706 and a buffer 707. Further, a level shifter may be included. In the scanning line driver circuit 702, a selection signal is generated by inputting a clock signal (CLK) and a start pulse signal (SP) to the shift register 706. The generated selection signal is buffer-amplified in the buffer 707, and then supplied to a corresponding scanning line. Gates of transistors of pixels of one line are connected to the scanning line. Further, since the transistors of the pixels of one line have to be turned on at the same time, a buffer to which a large current can be fed is used for the buffer 707.

In a full color liquid crystal display device, when video signals corresponding to R (red), G (green), and B (blue) are sampled in sequence and are each supplied to a corresponding signal line, the number of terminals for connecting the shift register 704 and the analog switch 705 corresponds to about ⅓ of that of terminals for connecting the analog switch 705 to the signal lines of the pixel portion 700. Consequently, by forming the analog switch 705 and the pixel portion 700 over the same substrate, the number of terminals used to connect a substrate over which a pixel portion is formed to a substrate which is formed separately can be suppressed compared to a case of forming the analog switch 705 and the pixel portion 700 over different substrates, and occurrence probability of poor connection can be suppressed, and the yield can be increased.

Although the scanning line driver circuit 702 in FIG. 32 includes the shift register 706 and the buffer 707, the scanning line driver circuit 702 may be constituted of only the shift register 706.

Note that the configuration shown in FIG. 32 is merely a mode of a display device of the present invention, and the configuration of a signal line driver circuit and a scanning line driver circuit is not limited thereto. In a display device including a circuit as shown in FIG. 32 which includes a thin film transistor in which a microcrystalline semiconductor film is used for a channel formation region, the circuit can operate at high speed. For example, when a transistor in which a microcrystalline semiconductor film is used for a channel formation region is compared to a transistor in which an amorphous semiconductor film is used for a channel formation region, the former has higher mobility, and thus can have a higher driving frequency in a driver circuit (e.g., the shift register 706 in the scanning line driver circuit 702). Since the scanning line driver circuit 702 can operate at high speed, increase in the frame frequency, black frame insertion, or the like can be realized.

When the frame frequency is increased, data for a screen is preferably generated in accordance with a direction of movement of an image. That is, motion compensation is preferably performed to interpolate data. When the frame frequency is increased and image data is interpolated in such a manner, display characteristics of moving images are improved, and smooth display can be performed. For example, when frame frequency is doubled (e.g., 120 Hz or 100 Hz) or more, preferably quadrupled (e.g., 480 Hz or 400 Hz) or more, blurring and afterimages of moving images can be reduced. In this case, the scanning line driver circuit 702 is also operated with a higher driving frequency; thus, the frame frequency can be increased.

When black frame insertion is performed, such a structure is formed that image data or data for black display can be supplied to the pixel portion 700. Thus, display is performed in a method similar to impulse driving, and afterimages can be reduced. In this case, the scanning line driver circuit 702 is also operated with a higher driving frequency; thus, black frame insertion can be performed.

In addition, by increasing the channel width of the thin film transistor in the scanning line driver circuit 702 or by providing a plurality of scanning line driver circuits, for example, still higher frame frequency can be realized. For example, the frame frequency can be octupled (e.g., 960 Hz or 800 Hz) or more. When a plurality of scanning line driver circuits are provided, a scanning line driver circuit for driving scanning lines in even-numbered rows is provided on one side and a scanning line driver circuit for driving scanning lines in odd-numbered rows is provided on the opposite side; thus, increase in frame frequency can be realized.

When the circuit as shown in FIG. 32 includes a transistor in which a microcrystalline semiconductor film is used for a channel formation region, the layout area can be reduced. Accordingly, the area of a frame of a liquid crystal display device, which is an example of the display device, can be reduced. For example, a transistor in which a microcrystalline semiconductor film is used for a channel formation region has higher mobility than a transistor in which an amorphous semiconductor film is used for a channel formation region; thus, the channel width of the transistor in which the microcrystalline semiconductor film is used for the channel formation region can be smaller. As a result, the frame of the liquid crystal display device can be narrow.

Note that a thin film transistor in which a microcrystalline semiconductor film is used for a channel formation region is less likely to deteriorate compared with a thin film transistor in which an amorphous semiconductor film is used for a channel formation region. Accordingly, when a microcrystalline semiconductor film is used for a channel formation region, the channel width of the thin film transistor can be reduced. Further, the thin film transistor can operate normally without any circuit for compensation for deterioration. Accordingly, the planar area of a thin film transistor in each pixel can be reduced.

### Embodiment Mode 9

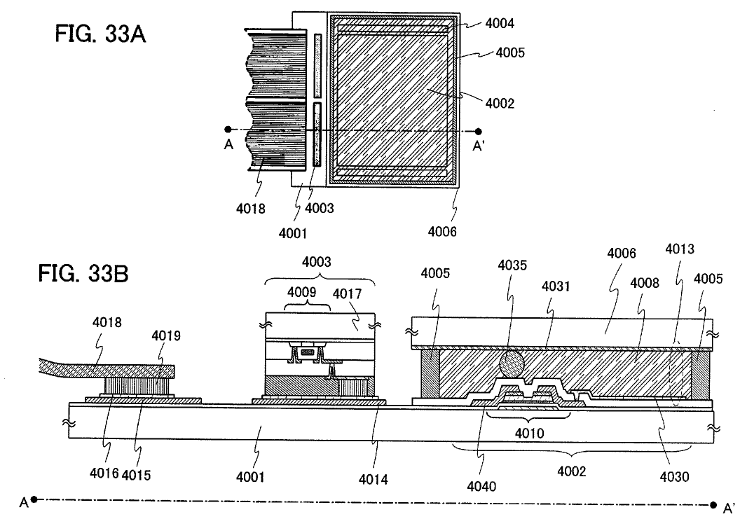

Next, an external view and a cross section of a liquid crystal display panel, which is one mode of a display device of the present invention, is described with reference to FIGS. 33A and 33B. FIG. 33A is a top view of a panel in which a thin film transistor 4010 including a microcrystalline semiconductor film and a liquid crystal element 4013 that are formed over a first substrate 4001 are sealed with a sealant 4005 between the first substrate 4001 and a second substrate 4006. FIG. 33B is a cross-sectional view taken along a line A-A′ in FIG. 33A.

The sealant 4005 is provided so as to surround a pixel portion 4002 and a scanning line driver circuit 4004 that are provided over the first substrate 4001. The second substrate 4006 is provided over the pixel portion 4002 and the scanning line driver circuit 4004. Thus, the pixel portion 4002 and the scanning line driver circuit 4004, together with liquid crystals 4008, are sealed with the sealant 4005 between the first substrate 4001 and the second substrate 4006. A signal line driver circuit 4003 that is formed using a polycrystalline semiconductor film over a substrate which is prepared separately is mounted in a region that is different from the region surrounded by the sealant 4005 over the first substrate 4001. This embodiment mode describes an example in which the signal line driver circuit including a thin film transistor in which a polycrystalline semiconductor film is used for a channel formation region is attached to the first substrate 4001. Alternatively, a signal line driver circuit may be formed using a thin film transistor in which a single-crystalline semiconductor film is used for a channel formation region and attached to the first substrate 4001. FIG. 33B shows a thin film transistor 4009 that is formed using a polycrystalline semiconductor film and included in the signal line driver circuit 4003 as an example.

The pixel portion 4002 and the scanning line driver circuit 4004 that are formed over the first substrate 4001 each include a plurality of thin film transistors, and the thin film transistor 4010 included in the pixel portion 4002 is shown as an example in FIG. 33B. The thin film transistor 4010 corresponds to a thin film transistor in which a microcrystalline semiconductor film is used for a channel formation region.

In addition, a pixel electrode 4030 of the liquid crystal element 4013 is electrically connected to the thin film transistor 4010 through a wiring 4040. A counter electrode 4031 of the liquid crystal element 4013 is formed on the second substrate 4006. The liquid crystal element 4013 corresponds to a region where the pixel electrode 4030 and the counter electrode 4031 sandwich the liquid crystals 4008.

The first substrate 4001 and the second substrate 4006 can be formed using glass, metal (a typical example is stainless steel), ceramics, or plastics. As plastics, a fiberglass-reinforced plastics (FRP) plate, a polyvinyl fluoride (PVF) film, a polyester film, or an acrylic resin film can be used. Further, a sheet in which aluminum foil is sandwiched by PVF films or polyester films can also be used.

A spherical spacer 4035 is provided to control a distance (a cell gap) between the pixel electrode 4030 and the counter electrode 4031. Further, a spacer which is obtained by selectively etching an insulating film may also be used.

The signal line driver circuit 4003 that is formed separately is formed on a substrate 4017. A variety of signals and potential are supplied to the scanning line driver circuit 4004 or the pixel portion 4002 through leading wirings 4014 and 4015 from an FPC 4018.

In this embodiment mode, a connecting terminal 4016 is formed of the same conductive film as that of the pixel electrode 4030 included in the liquid crystal element 4013. In addition, the leading wirings 4014 and 4015 are formed of the same conductive film as that of the wiring 4040.

The connecting terminal 4016 is electrically connected to a terminal of the FPC 4018 through an anisotropic conductive film 4019.

Although not illustrated, the liquid crystal display device shown in this embodiment mode includes an alignment film, a polarizing plate, and further, may include a color filter.

FIGS. 33A and 33B show an example in which the signal line driver circuit 4003 is formed separately and mounted on the first substrate 4001, but this embodiment mode is not limited to this structure. The scanning line driver circuit may be formed separately and then mounted, or only a part of the signal line driver circuit or a part of the scanning line driver circuit may be formed separately and then mounted.

This embodiment mode can be carried out in combination with a structure of another embodiment mode.

### Embodiment Mode 10

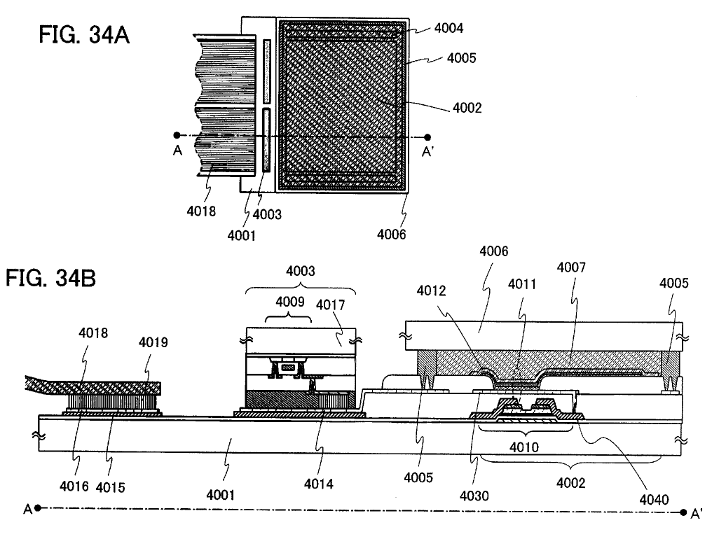

Next, an external view and a cross section of a light-emitting display panel, which is one mode of a display device of the present invention, is described with reference to FIGS. 34A and 34B. FIG. 34A is a top view of a panel in which a thin film transistor including a microcrystalline semiconductor film and a light-emitting element that are formed over a first substrate are sealed with a sealant between the first substrate and a second substrate. FIG. 34B is a cross-sectional view taken along a line A-A′ in FIG. 34A.

A sealant 4005 is provided so as to surround a pixel portion 4002 and a scanning line driver circuit 4004 that are provided over a first substrate 4001. A second substrate 4006 is provided over the pixel portion 4002 and the scanning line driver circuit 4004. Thus, the pixel portion 4002 and the scanning line driver circuit 4004, together with a filler 4007, are sealed with the sealant 4005 between the first substrate 4001 and the second substrate 4006. A signal line driver circuit 4003 that is formed using a polycrystalline semiconductor film over a substrate which is prepared separately is mounted in a region that is different from the region surrounded by the sealant 4005 over the first substrate 4001. This embodiment mode describes an example in which the signal line driver circuit including a thin film transistor in which a polycrystalline semiconductor film is used for a channel formation region is attached to the first substrate 4001. Alternatively, a signal line driver circuit may be formed using a thin film transistor in which a single-crystalline semiconductor is used for a channel formation region, and may be attached to the first substrate 4001. FIG. 34B shows a thin film transistor 4009 that is formed using a polycrystalline semiconductor film and included in the signal line driver circuit 4003 as an example.

The pixel portion 4002 and the scanning line driver circuit 4004 that are provided over the first substrate 4001 each include a plurality of thin film transistors. FIG. 34B shows a thin film transistor 4010 included in the pixel portion 4002 as an example. In this embodiment mode, the thin film transistor 4010 is illustrated as a driving TFT but may also be a current control TFT or an erasing TFT. The thin film transistor 4010 corresponds to a thin film transistor in which a microcrystalline semiconductor film is used for a channel formation region.

A pixel electrode 4030 of a light-emitting element 4011 is electrically connected to a wiring 4040 that serves as a source or drain electrode of the thin film transistor 4010. Further in this embodiment mode, a light-transmitting conductive film 4012 of the light-emitting element 4011 is formed over the pixel electrode 4030 with a light-emitting layer interposed therebetween. The structure of the light-emitting element 4011 is not limited to that described in this embodiment mode. The structure of the light-emitting element 4011 can be changed as appropriate in accordance with a direction of light taken from the light-emitting element 4011, polarity of the thin film transistor 4010, or the like.

The signal line driver circuit 4003 that is formed separately is formed on a substrate 4017. A variety of signals and potential are applied to the scanning line driver circuit 4004 or the pixel portion 4002 from an FPC 4018 through leading wirings 4014 and 4015, although not illustrated in the cross-sectional view of FIG. 34B.

In this embodiment mode, a connecting terminal 4016 is formed of the same conductive film as that of the pixel electrode 4030 included in the light-emitting element 4011. In addition, the leading wirings 4014 and 4015 are formed of the same conductive film as that of the wiring 4040.

The connecting terminal 4016 is electrically connected to a terminal of the FPC 4018 through an anisotropic conductive film 4019.

A substrate located in a direction of extracting light from the light-emitting element 4011 needs to be transparent. In that case, a light-transmitting material such as a glass plate, a plastic plate, a polyester film, or an acrylic film is used.

As the filler 4007, an ultraviolet curable resin or a thermosetting resin can be used as well as an inert gas such as nitrogen or argon. For example, polyvinyl chloride (PVC), acrylic, polyimide, an epoxy resin, a silicone resin, polyvinyl butyral (PVB), or ethylene vinyl acetate (EVA) can be used. In this embodiment mode, nitrogen is used as the filler.

If necessary, an optical film such as a polarizing plate, a circularly polarizing plate (including an elliptically polarizing plate), a retardation plate (a quarter-wave plate or a half-wave plate), or a color filter may be provided as appropriate for a light-emitting surface of the light-emitting element. Further, a polarizing plate or a circularly polarizing plate may be provided with an anti-reflection film. For example, antiglare treatment may be carried out, by which reflected light can be diffused by projections and depressions on a surface, thereby reducing reflection.

FIGS. 34A and 34B show an example in which the signal line driver circuit 4003 is formed separately and mounted on the first substrate 4001, but this embodiment mode is not limited to this structure. The scanning line driver circuit may be formed separately and then mounted, or only a part of the signal line driver circuit or a part of the scanning line driver circuit may be formed separately and then mounted.

This embodiment mode can be carried out in combination with a structure of another embodiment mode.

### Embodiment Mode 11

Display devices or the like that are obtained according to the present invention can be used for active matrix display device modules. That is to say, the present invention can be carried out in all electronic appliances in which these modules are incorporated into display portions.

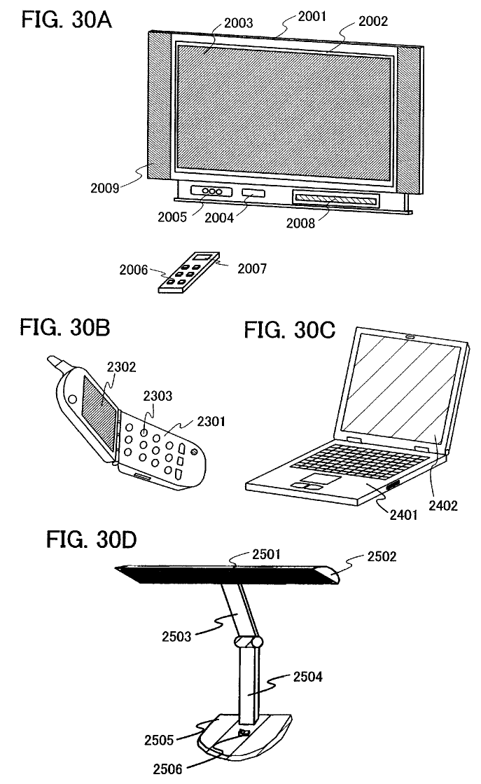

As such electronic appliances, cameras such as video cameras and digital cameras, displays that can be mounted on a person's head (goggle-type displays), car navigation systems, projectors, car stereos, personal computers, portable information terminals (e.g., mobile computers, mobile phones, and electronic books), and the like can be given. Examples of these appliances are illustrated in FIGS. 30A to 30D.

FIG. 30A shows a television device. A television device can be completed by incorporating a display module into a chassis as shown in FIG. 30A. A display panel including components up to an FPC is also referred to as a display module. A main screen 2003 is formed with a display module. In addition, a speaker unit 2009, operation switches, and the like are provided as accessory equipment. In this manner, a television device can be completed.

As shown in FIG. 30A, a display panel 2002 including display elements is incorporated into a chassis 2001. In addition to reception of general television broadcast by a receiver 2005, communication of information in one direction (from a transmitter to a receiver) or in two directions (between a transmitter and a receiver or between receivers) can be performed by connection to a wired or wireless communication network through a modem 2004. The television device can be operated using switches that are incorporated in the chassis or with a remote control device 2006 that is provided separately, and a display portion 2007 that displays output information may be provided for the remote control device.

Further, in the television device, a sub-screen 2008 may be formed using a second display panel and may be used to display channel number, volume, and the like, in addition to the main screen 2003. In this structure, the main screen 2003 may be formed with a liquid crystal display panel, and the sub-screen 2008 may be formed with a light-emitting display panel. Furthermore, the main screen 2003 may be formed with a light-emitting display panel, and the sub-screen 2008 may be formed with a light-emitting display panel, and the sub-screen 2008 may be configured to be capable of flashing on and off.

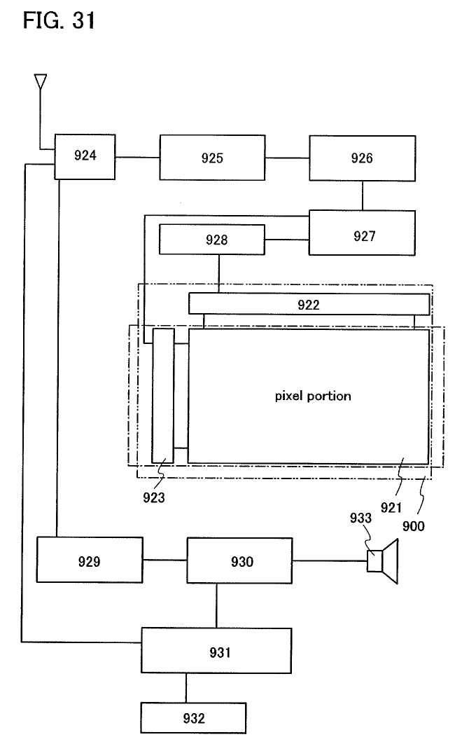

FIG. 31 is a block diagram showing a main structure of the television device. A pixel portion 921 is formed in a display panel 900. A signal line driver circuit 922 and a scanning line driver circuit 923 may be mounted on the display panel 900 by a COG method.

As other external circuits, a video signal amplifier circuit 925 that amplifies a video signal among signals received by a tuner 924, a video signal process circuit 926 that converts the signals output from the video signal amplifier circuit 925 into color signals corresponding to their respective colors of red, green, and blue, a control circuit 927 that converts the video signal so that the video signal can match input specification of the driver IC, and the like are provided on an input side of the video signal. The control circuit 927 outputs signals to both a scanning line side and a signal line side. In a case of digital driving, a signal divide circuit 928 may be provided on the signal line side and an input digital signal may be divided into m pieces and supplied.

An audio signal among signals received by the tuner 924 is sent to an audio signal amplifier circuit 929 and is supplied to a speaker 933 through an audio signal process circuit 930. A control circuit 931 receives control information of a receiving station (reception frequency) or sound volume from an input portion 932 and transmits signals to the tuner 924 and the audio signal process circuit 930.

Needless to say, the present invention is not limited to a use for television devices, and can be applied to a variety of applications such as monitors of personal computers, or display media that have a large area, such as information display boards in railway stations, airports, and the like, or street-side advertisement display boards.

FIG. 30B shows one mode of a mobile phone 2301. The mobile phone 2301 includes a display portion 2302, an operation portion 2303, and the like. The display device described in the preceding embodiment modes is applied to the display portion 2302, so that mass productivity can be improved.

A portable computer shown in FIG. 30C includes a main body 2401, a display portion 2402, and the like. The display device described in the preceding embodiment modes is applied to the display portion 2402, so that mass productivity can be improved.

FIG. 30D shows a desk lamp including a lighting portion 2501, a lampshade 2502, an adjustable arm 2503, a support 2504, a base 2505, and a power supply 2506. The desk lamp is manufactured using a light-emitting device described in Embodiment Mode 7 of the present invention for the lighting portion 2501. The lighting equipment includes a ceiling light, a wall light, and the like in its category. Use of the display device presented in Embodiment Mode 7 can increase mass productivity and provide inexpensive desk lamps.

This application is based on Japanese Patent Application serial No. 2007-305294 filed with Japan Patent Office on Nov. 27, 2007, the entire contents of which are hereby incorporated by reference.

What is claimed is:

1. A method for manufacturing a semiconductor device, comprising the steps of:
placing a substrate into a reaction chamber, the reaction chamber being provided in a deposition chamber with space between the reaction chamber and the deposition chamber;
supplying a sealing gas into the space;
supplying a reaction gas into the reaction chamber; and
forming a semiconductor film over the substrate by a plasma enhanced chemical vapor deposition method in the reaction chamber.

2. The method for manufacturing a semiconductor device according to claim 1, wherein in forming the semiconductor film, fluorine or a gas including fluorine is supplied into the reaction chamber.

3. The method for manufacturing a semiconductor device according to claim 1, wherein in forming the semiconductor film, phosphine is supplied into the reaction chamber.

4. The method for manufacturing a semiconductor device according to claim 1, further comprising the step of supplying fluorine or a gas including fluorine into the reaction chamber and generating plasma before placing the substrate into the reaction chamber.

5. The method for manufacturing a semiconductor device according to claim 1, further comprising the step of supplying phosphine into the reaction chamber and generating plasma before placing the substrate into the reaction chamber.

6. The method for manufacturing a semiconductor device according to claim 1,
wherein the sealing gas comprises at least one of a hydrogen gas and a rare gas; and
wherein a concentration of an element except a hydrogen gas and a rare gas is lower than or equal to 10⁻⁷ atoms %.

7. A method for manufacturing a semiconductor device, comprising the steps of:
forming a gate electrode over a substrate;
forming a gate insulating film on the gate electrode;
after forming the gate insulating film, placing the substrate into a reaction chamber, the reaction chamber being provided in a deposition chamber with space between the reaction chamber and the deposition chamber;
supplying a sealing gas into the space;
supplying a reaction gas into the reaction chamber; and
forming a microcrystalline semiconductor film on the gate insulating film by a plasma enhanced chemical vapor deposition method in the reaction chamber,
wherein a deposition rate is increased stepwise or gradually in a growth direction of the microcrystalline semiconductor film from the substrate side in forming the microcrystalline semiconductor film.

8. The method for manufacturing a semiconductor device according to claim 7, wherein in forming the microcrystalline semiconductor film, fluorine or a gas including fluorine is supplied into the reaction chamber.

9. The method for manufacturing a semiconductor device according to claim 7, wherein in forming the microcrystalline semiconductor film, phosphine is supplied into the reaction chamber.

10. The method for manufacturing a semiconductor device according to claim 7, further comprising the step of supplying fluorine or a gas including fluorine into the reaction chamber and generating plasma before placing the substrate into the reaction chamber.

11. The method for manufacturing a semiconductor device according to claim 7, further comprising the step of supplying phosphine into the reaction chamber and generating plasma before placing the substrate into the reaction chamber.

12. The method for manufacturing a semiconductor device according to claim 7,
wherein the sealing gas comprises at least one of a hydrogen gas and a rare gas; and
wherein a concentration of an element except a hydrogen gas and a rare gas is lower than or equal to 10⁻⁷ atoms %.

13. A method for manufacturing a semiconductor device, comprising the steps of:
forming a gate electrode over a substrate;
forming a gate insulating film on the gate electrode;
after forming the gate insulating film, placing the substrate into a reaction chamber, the reaction chamber being provided in a deposition chamber with space between the reaction chamber and the deposition chamber;
supplying a sealing gas into the space and supplying a reaction gas into the reaction chamber;
forming a microcrystalline semiconductor film on the gate insulating film by a plasma enhanced chemical vapor deposition method in the reaction chamber,
forming a buffer layer on the microcrystalline semiconductor film, the buffer layer comprising an amorphous semiconductor film including hydrogen, nitrogen or halogen, and
forming a semiconductor film on the buffer layer, the semiconductor film including an impurity element imparting one conductivity type,
wherein a deposition rate is increased stepwise or gradually in a growth direction of the microcrystalline semiconductor film from the substrate side in forming the microcrystalline semiconductor film.

14. The method for manufacturing a semiconductor device according to claim 13, wherein in forming the microcrystalline semiconductor film, fluorine or a gas including fluorine is supplied into the reaction chamber.

15. The method for manufacturing a semiconductor device according to claim 13, wherein in forming the microcrystalline semiconductor film, phosphine is supplied into the reaction chamber.

16. The method for manufacturing a semiconductor device according to claim 13, further comprising the step of supplying fluorine or a gas including fluorine into the reaction chamber and generating plasma before placing the substrate into the reaction chamber.

17. The method for manufacturing a semiconductor device according to claim 13, further comprising the step of supplying phosphine into the reaction chamber and generating plasma before placing the substrate into the reaction chamber.

18. The method for manufacturing a semiconductor device according to claim 13,
wherein the sealing gas comprises at least one of a hydrogen gas and a rare gas; and
wherein a concentration of an element except a hydrogen gas and a rare gas is lower than or equal to 10⁻⁷ atoms %.
